(19) United States
(12) Patent Application Publication
(10) Pub. No.: US 2019/0214173 A1
(43) Pub. Date: Jul. 11, 2019

(54) AN APPARATUS FOR TRANSFERRING HEAT FROM A HEAT SOURCE TO A HEAT SINK

(71) Applicant: Nanyang Technological University, Singapore (SG)

(72) Inventors: Raju V. RAMANUJAN, Singapore (SG); Varun CHAUDHARY, Singapore (SG)

(21) Appl. No.: 16/323,220

(22) PCT Filed: Aug. 3, 2017
(86) PCT No.: PCT/SG2017/050392

§ 371 Date: Feb. 4, 2019

(30) Foreign Application Priority Data
Aug. 4, 2016 (SG) 10201606447V

(51) Int. Cl. H01F 1/44; H01L 23/473; F25B 21/00; H02K 9/19

(52) U.S. Cl. CPC H01F 1/445; H02K 9/19; F25B 21/00; H01L 23/473

(57) ABSTRACT

An apparatus for transferring heat from a heat source to a heat sink is disclosed. The apparatus comprises: a conduit containing a ferrofluid which comprises a plurality of magnetic nanoparticles, a first portion of the conduit being thermally coupleable to the heat source and a second portion of the conduit being thermally coupleable to the heat sink; and a magnetic element arranged to provide a magnetic field to the ferrofluid; wherein the magnetic element is located upstream of the first portion to drive a flow of the ferrofluid in the direction of the heat source.

### FIELD OF THE INVENTION

The present invention relates to an apparatus for transferring heat from a heat source to a heat sink. In particular, the invention relates to the use of a ferrofluid for heat transfer.

### BACKGROUND

Many thermal management solutions have been suggested to reduce temperature (see references 1-8 at the end of the description). Current cooling approaches for thermal management like micro jet cooling and spray cooling have been widely used in electronic devices (see references 5-8). However, these techniques have some drawbacks, e.g., vibration, noise, leakage, high maintenance and high power consumption due to mechanical pumps and other moving parts. To overcome these drawbacks, researchers are trying to avoid mechanical pumps and have proposed membrane based actuators, for example (i) magnetic (ii) piezoelectric (iii) thermo-pneumatic and (iv) shape memory alloy actuators (see references 9-11). However, these techniques generally provide a pulsating flow rate, resulting in temperature fluctuations which create instabilities. There is another method in which the electric force effect is utilized for pumping conductive fluid. This approach provides a smooth flow, however, in general, the limitation is the requirement of high voltage. In addition, to find a working fluid with suitable electrical conductivity is also a big challenge.

Approximately, 40% of all foods require refrigeration, and 15% of electricity consumed is for this application (see reference 12). However, in reality less than 10% of such perishable foods are in fact currently refrigerated. It has been estimated that post-harvest losses account for 30% of total production (see reference 13). The production of food involves a significant carbon investment that is worthless if the food is then not utilised. With the concern over climate change, global warming and energy costs, it is important to focus on significant reductions in carbon emissions and energy use. A cold chain temperature is stabilised in supermarkets in cities. However, there is no strong cold chain link to the consumer, resulting in spoiling of foods.

In addition, some diseases like polio are challenging because of the sensitive nature of vaccines to temperature. These vaccines spoil if not kept at a precise temperature all the time from manufacturer to patient. Unfortunately, in many remote areas of the developing world, there is an absence of infrastructure and electricity to maintain a temperature controlled system. As a result, numerous lifesaving vaccines spoil before their use. Therefore, there is an urgent need for an energy efficient temperature controlled system.

Recently, Rogers Corporation's power electronics solutions group has released new cooling system called “Curamik® CoolPerformance Plus” for laser diodes (see reference 14). They have used ceramic aluminum nitrate isolation layers to separate cooling water channels from the electrical contacts of laser diodes. This system can dissipate large amounts of heat and provide reliable thermal management for high-power laser diodes and other heat-generating optical devices.

Asus' water cooled gaming laptops (GX700) are already in the market. However, the water-cooling system is not particularly portable and the water-cooling dock containing all of the liquid-cooling components can become undocked from the laptop via quick-disconnects (see reference 15). This system comprises two radiators and fans under vents, along with a pump and reservoir. It is therefore extremely bulky.

A paper available on ResearchGate entitled “Potential of enhancing a natural convection loop with a thermomagnetically pumped ferrofluid” by Eskil Aursand et al. describes a cooling apparatus in which a conduit filled with ferrofluid is arranged to transfer heat from a heat source to a heat sink wherein an electromagnet is provided around the heat source.

It is an aim of the present invention to provide an improved or at least alternative apparatus for transferring heat from a heat source to a heat sink for one or more of the aforementioned applications.

### SUMMARY OF THE INVENTION

In accordance with a first aspect of the invention there is provided an apparatus for transferring heat from a heat source to a heat sink. The apparatus comprises:

a conduit containing a ferrofluid which comprises a plurality of magnetic nanoparticles; a first portion of the conduit being thermally coupleable to the heat source and a second portion of the conduit being thermally coupleable to the heat sink; and

a magnetic element arranged to provide a magnetic field to the ferrofluid;

wherein the magnetic element is located upstream of the first portion to drive a flow of the ferrofluid in the direction of the heat source.

Thus, embodiments of present invention provide an apparatus for transferring heat from a heat source to a heat sink using a thermomagnetically pumped ferrofluid which does not require an external pumping device and therefore it is mechanically stable, vibration-free and maintenance free. Notably, no additional energy, other than waste heat which is dissipated, is consumed in this proposed self-pumped cooling system. More specifically, the apparatus is configured to exploit a thermomagnetic pumping force induced by heat from the heat source and controlled by the magnetisation of the ferrofluid. A particular advantage is that the apparatus is self-regulating because a larger temperature gradient between the heat source and heat sink will result in a decrease in magnetisation of the ferrofluid which in turn will cause a driving force for fluid motion to increase thereby pumping the ferrofluid faster which will in turn reduce the temperature gradient.

A particular advantage of locating the magnetic element upstream of the first portion (and therefore upstream of the heat source) is that the ferrofluid further upstream of the region of the magnetic element will be relatively cool (and therefore more magnetised) and the ferrofluid downstream of the magnetic element will be relatively hot (and therefore less magnetised) due to the presence of the heat source and this temperature gradient will help to drive a flow of the ferrofluid in the direction of the heat source (since the more magnetised cool ferrofluid will have a stronger attraction to the magnetic field than the less magnetised hot ferrofluid). Furthermore, this design means that the magnetic element can be placed in close proximity to the conduit (for maximum magnetisation of the ferrofluid) whilst also allowing the heat source to be placed in close proximity to the conduit (for optimum heat transfer). The location of the magnetic element upstream of the heat source also ensures that the space available for the heat source is not restricted due the presence of the magnetic element.

The magnetic element may be located in a region of the conduit adjacent to the first portion.

In some embodiments, multiple conduits may be employed, each containing a ferrofluid which comprises a plurality of magnetic nanoparticles, and each having a first portion thermally coupleable to the heat source and a second portion thermally coupleable to the heat sink. Two or more of the conduits may be stacked, nested, aligned, concentric, adjacent or level with each other. In some embodiments, an array of conduits may be provided.

The (or each) conduit may be configured as a loop, a helix or a spiral. The (or each) loop, helix or spiral may be circular, oval, square, triangular, rectangular or shaped as another polygon or regular or irregular shape. In use, the (or each) conduit may provide a path for the ferrofluid that is substantially horizontal.

The apparatus may further comprise a temperature sensor configured to monitor the temperature of the heat source; and a control system configured to adjust the magnetic field provided to the ferrofluid to thereby adjust a cooling rate based on the temperature of the heat source. Thus, further control of the cooling rate or pump rate of the system may be provided in addition to the self-regulating nature of the ferrofluid itself. This additional degree of control may be advantageous in applications where it is desirable to maintain the heat source within a pre-defined temperature range. In which case, if the cooling rate was not manipulated by the control system, the ferrofluid may continue to cool the heat source below a minimum level.

The magnetic element may be constituted by a permanent magnet or an electromagnet.

In the case of a permanent magnet, the control system may be configured to move the permanent magnet towards or away from the ferrofluid to thereby control the magnetic field provided to the ferrofluid. The control system may comprise a movable stage configured for moving the permanent magnet.

In the case of an electromagnet, the control system may be configured to adjust current flowing through a solenoid wire to thereby control the magnetic field provided to the ferrofluid.

The apparatus may further comprise a chamber having an outer portion and an inner portion. The inner portion may be configured to accommodate the heat source. The outer portion may be configured to accommodate the heat sink.

The first portion of the conduit may be arrange to be opposite the second portion of the conduit such that the heat source is arranged to be opposite the heat sink.

In a particular embodiment, the heat source may be arranged centrally within the inner portion of the chamber and one or more heat sinks may be arranged in the outer portion of the chamber.

In another embodiment, both the heat source and the heat sink may be provided within the inner portion of the chamber.

The chamber may comprise a lid for securing the heat source there-within.

The magnetic nanoparticles may comprise MnZn Ferrite and/or Iron Nickel Chromium alloy. More specifically, the magnetic nanoparticles may comprise Mn_{0.4}Zn_{0.6}Fe₂O₄ and/or (Fe₇₀Ni₃₀)₁₀₀₋ₓCrₓ, where x is from 0 to 7.0. For example, the nanoparticles may comprise (Fe₇₀Ni₃₀)₉₅Cr₅.

The magnetic field may be static or dynamic.

The heat source may be constituted by an electronic device, a micro-electromechanical system (MEMS); a vaccine; an engine; a solar panel; food or drink.

Applications are plentiful and include the fields of automobiles, aeroplanes, ships, spacecraft, consumer devices, cold chain storage, defense and domestic or commercial buildings etc.

The heat sink may comprise air, water, sea, ice, dry ice or another fluid.

The apparatus may be designed to provide a desired performance based on a load provided by the heat source; a temperature of the heat sink; a strength of the magnetic field; a shape or configuration of the apparatus; a shape, diameter and number of conduits; a size, type and density of the magnetic nanoparticles; and properties of a base fluid comprised in the ferrofluid.

### BRIEF DESCRIPTION OF THE DRAWINGS

Embodiments of the invention will now be described, by way of example only, with reference to the following drawings, in which:

FIG. 1 is a graph of temperature dependence of magnetisation for magnetic nanoparticles MnₓZn₁₋ₓFe₂O₄ (where x=0.3, 0.4 and 0.5, respectively) at an applied magnetic field of 100 Oe;

FIG. 2 shows a schematic layout of an apparatus for transferring heat from a heat source to a heat sink, in accordance with an embodiment of the invention;

FIG. 3(a) shows a schematic of a 2D model of the apparatus of FIG. 2 showing temperature distribution without an applied magnetic field;

FIG. 3(b) shows a schematic of a 2D model of the apparatus of FIG. 2 showing temperature distribution with an applied magnetic field;

FIG. 4 shows a graph of temperature against time when various magnetic field strengths are applied to the apparatus of FIG. 2;

FIG. 5 shows a temperature difference of a heat load with and without an applied magnetic field;

FIGS. 6A, 6B, and 6C show heat load temperatures against time for an initial temperature of (a) 64° C., (b) 74° C. and (c) 87° C., respectively, without and with a magnetic field of 0.3 T;

FIG. 7 shows a temperature difference of the heat loads of FIG. 6 with and without the applied magnetic field;

FIG. 8 shows a graph of temperature against time for different volume fractions of magnetic nanoparticles;

FIG. 9 shows a temperature difference of a heat load for different volume fraction of magnetic nanoparticles;

FIGS. 10A, 10B, and 10C show temperatures against time graphs for an initial temperature of a heat load of (a) 87° C., (b) 74° C. and (c) 64° C., respectively, showing the effect of application and removal of a magnetic field of 0.3 T;

FIG. 11 shows a temperature against time graph for a heat load, showing the effect of application and removal of a magnetic field of 0.3 T when a square conduit is employed;

FIG. 12 shows an apparatus according to an embodiment of the invention in which six circular conduits are employed;

FIG. 13 shows an apparatus according to an embodiment of the invention in which three concentric conduits are employed;

FIG. 14 shows an apparatus according to an embodiment of the invention in which a single spiral conduit is employed; and

FIGS. 15A and 15B show temperatures against time graphs for an initial temperature of a heat load of (a) 160.5° C. and (b) 136.8° C., respectively, showing the effect of application and removal of a magnetic field of 0.4 T.

FIG. 16 shows the XRD patterns of Cr0, Cr1, Cr3, Cr5, Cr6 and Cr7 nanoparticles after heating at 700° C. for 2 h followed by quenching.

FIGS. 17A and 17B depict bright field TEM micrographs of (a) Cr3 and (b) Cr5 nanoparticles, insets show lattice fringe images corresponding to 111 planes.

FIGS. 18A, 18B, 18C, 18D, 18E, and 18F: Left axis shows the temperature dependence of magnetization M(T) for (a) Cr0, (b) Cr1, (c) Cr3, (d) Cr5, (e) Cr6 and (f) Cr7 while the right axis shows the corresponding derivative with respect to temperature (dM/dT). The Curie temperature for Cr0, Cr1, Cr3, Cr5, Cr6 and Cr7 is 438 K, 398 K, 323 K, 258 K, 245 K and 215 K, respectively.

FIGS. 19A and 19B: (a) The Bethe-Slater curve (schematic) showing the dependence of the exchange interaction on the ratio of interatomic distance to the diameter of the 3d electron shell; (b) Phase diagram for the ternary system (Fe₇₀Ni₃₀)₁₀₀₋ₓCrₓ for x=0 to 8. Dashed line represents the values predicted from the equation T_{C}=T_{C1}+(T_{C}/dc) (c) while points (squares) are experimental results.

FIGS. 20A, 20B, 20C, 20D, 20E and 20F: Temperature dependence of magnetic entropy change (−ΔS_{M}) under magnetic field ranging from 0.5 T to 5 T for (a) Cr1, (b) Cr3, (c) Cr5, (d) Cr6 and (e) Cr7 alloy. (f) Dependence of −ΔS_{M} (left axis, square) and RCP (right axis, circle) on chromium content in (Fe₇₀Ni₃₀)₁₀₀₋ₓCrₓ nanoparticles at applied magnetic field of 5 T.

FIGS. 21A, 21B, and 21C: (a) Field dependence of working temperature span (δT_{FWHM}) for Cr1, Cr3, Cr5 Cr6 and Cr7 alloys. (b) Variation in relative cooling power (RCP) and (c) maximum change in entropy (−ΔS_{M}^{max}) as a function of applied field. The plots (b) and (c) are in log-log scale.

FIGS. 22A, 22B, 22C, 22D, 22E, and 22F: Temperature v/s time for initial temperature of heat load of (a) 64.4° C., (b) 53.4° C. and (c) 47.4° C., respectively, without and with magnetic field of 0.25 T. Simulated temperature profiles without and with magnetic field of 0.25 T for corresponding temperature of heat load of (d) 64.4° C., (e) 53.4° C. and (f) 47.4° C.

### DETAILED DESCRIPTION

Embodiments of the invention relate to apparatus for transferring heat from a heat source to a heat sink using a ferrofluid. The body force in ferrohydrodynamics (FHD) is a result of a change in a material's magnetisation with temperature in the presence of an applied magnetic field. The mechanics of such a body force depend on the properties of a colloidal suspension of ferro- or ferromagnetic single domain nanoparticles in a suitable liquid carrier or base (e.g. water, oil or kerosene) which together form a so-called ferrofluid. A ferrofluid experiences a change in magnetisation when the temperature of the ferrofluid changes. Under an applied magnetic field, larger magnetisation in a low temperature region compared to the magnetisation in a high temperature region, can produce a driving force inducing flow of the ferrofluid without an external pump. This phenomenon can therefore be used for a heat transfer in a range of cost-effective applications as will be described in more detail below.

### Magnetic Nanoparticles

In an embodiment of the invention, MnZn ferrite nanoparticles, synthesized by a hydrothermal method which comprised first functionalizing the nanoparticles by oleic acid and ammonium hydroxide, and then dispersing them into water to make the ferrofluid. The average diameter of the nanoparticles suspended in the ferrofluid was measured by a transmission electron microscope to be approximately 11 nm.

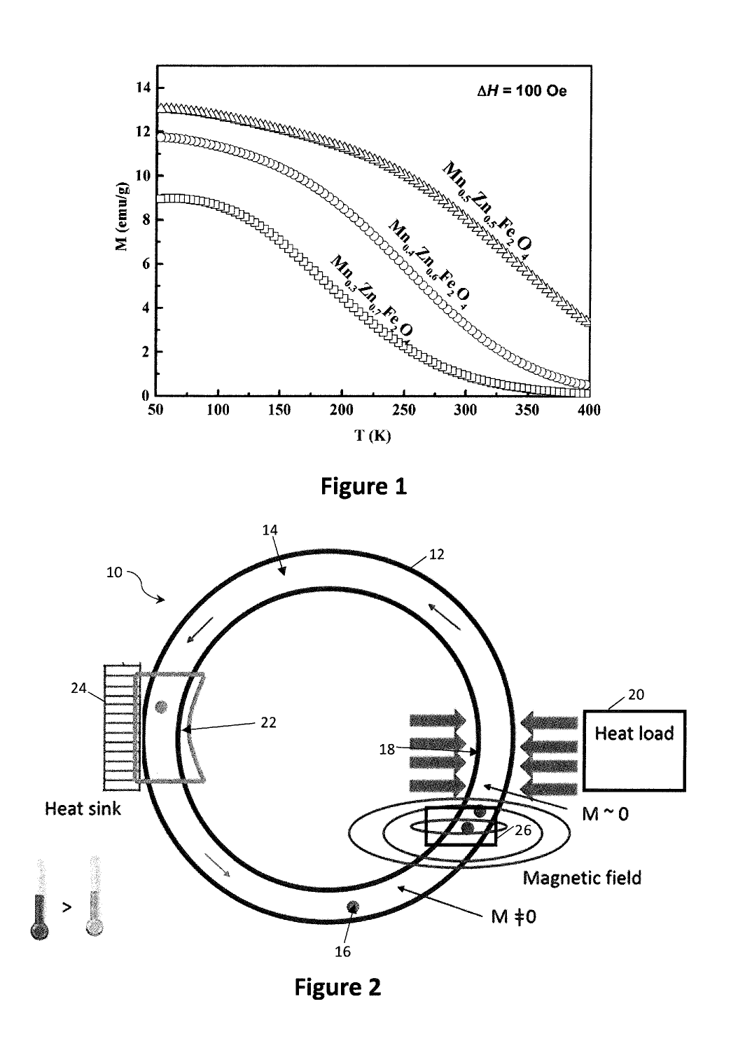

The magnetic properties of the nanoparticles were measured using a physical property measurement system (PPMS, EverCool-II Quantum Design) and FIG. 1 shows the temperature dependence of the magnetisation for different ratios of Mn and Zn in the Mn—Zn ferrite nanoparticles under an applied magnetic field of 500 Oe (0.05 T). More specifically, the magnetic nanoparticles tested were in accordance with the formula MnₓZn₁₋ₓFe₂O₄ where x=0.3, 0.4 and 0.5, respectively.

As can be seen from FIG. 1, all three materials have different magnetisation and Curie temperature (at which the materials lose their permanent magnetism). More particularly, the higher the ratio of Mn particles, the higher the magnetisation and the higher the Curie temperature.

In light of these results, the applicant proposes tuning the Curie temperature of the nanoparticles by changing the ratio of Mn and Zn so as to achieve cooling for waste heat in different temperature ranges. In other words, the composition of the nanoparticles may be chosen for a specific application.

In another embodiment, Fe—Ni based nanoparticles were developed in a high energy ball milling process for use in a ferrofluid. The nanoparticles were added along with oleic acid and ammonium hydroxide into a vial and milled for 10 hours to provide coated nanoparticles which were then dispersed in silicone oil, oleyl-amine and octadecane to form the ferrofluid. Accordingly, experiments were performed using a ferrofluid of (Fe₇₀Ni₃₀)₉₅Cr₅ nanoparticles and oleic acid.

### Basic Apparatus

In accordance with a first embodiment of the present invention there is provided an apparatus 10 for transferring heat from a heat source to a heat sink as illustrated in FIG. 2. The apparatus 10 comprises a conduit 12 containing a ferrofluid 14 which comprises a plurality of magnetic nanoparticles 16 (such as those described above). A first portion 18 of the conduit 12 is thermally coupled to the heat source 20 and a second portion 22 of the conduit 12 is thermally coupled to the heat sink 24. A magnetic element 26 is arranged to provide a magnetic field to the ferrofluid 14. Notably, the magnetic element 26 is located upstream of the first portion 18 to drive a flow of the ferrofluid 14 in the direction of the heat source 20.

In this embodiment, the conduit 12 is constituted by a circular polymer tube having a 5.2 mm inner diameter and a 60 cm circumference. The conduit 12 is configured as a circular loop lying in a horizontal plane (to avoid a buoyancy effect) and a spirit level was used to verify this. The heat source 20 (also known as a heat load) was an electric heater made by Kanthal wires and the heat sink 24 was in the form of an ice bath. The heat source 20 and heat sink 24 were located at opposite portions of the conduit 12. The magnetic element 26 was in the form of a permanent magnet providing a maximum magnetic field of 0.3 T. The magnetic element 26 was positioned close to an upstream end of the heat source 20.

A temperature data logger and memory card (not shown) were used to record the temperature of the heat source 20 against time. An initial temperature of the heat source 20 was selected by tuning the power via the current through the Kanthal wire and voltage supply using a Keithley power supply (Model: 2231 A-30-3). Experiments were carried out for heat loads 20 of 3.25 W, 4.4 W and 5.75 W which corresponded to waste heat at a temperature of 64° C., 74° C. and 87° C., respectively.

For modelling purposes, COMSOL Multiphysics simulation software version 4.4 was used with a finite element method and normal mesh. A value of magnetic susceptibility in the model was calculated from the magnetic susceptibility of the magnetic nanoparticles 16 and the volume concentration of the nanoparticles 16 in the ferrofluid 14. Water is a diamagnetic material and a typical value of volume magnetic susceptibility was ˜−9.0×10⁻⁶. The Navier-Stokes equation was used to describe the behavior of incompressible and viscous laminar flow of the ferrofluid 14 inside the conduit 12. In the model, the ferrofluid 14 was assumed to be a single phase, incompressible, and Newtonian fluid. No slip boundary condition was applied to the walls of the conduit 12. The properties of the ferrofluid 14 in the models were; density ρ=1044 kg-m³, specific heat C_{P}=1616 J-kg⁻¹K⁻¹, and thermal conductivity k=0.16 W-m⁻¹K⁻¹. For a thermal boundary condition, a constant surface temperature (273.15 K) was applied to the first portion 18 of the conduit 12 which was thermally coupled to the heat source 20 and to second portion 22 of the conduit 12 which was thermally coupled to the heat sink 24.

As will be explained in more detail below, in use, it was observed that the driving force for the ferrofluid 14 is a result of both magnetic and thermal gradients and the temperature distribution of the ferrofluid 14 can be controlled by changing the applied magnetic field. The effects of the magnetic field and load temperature on the cooling were studied and the results are presented below.

### Effect of Magnetic Field

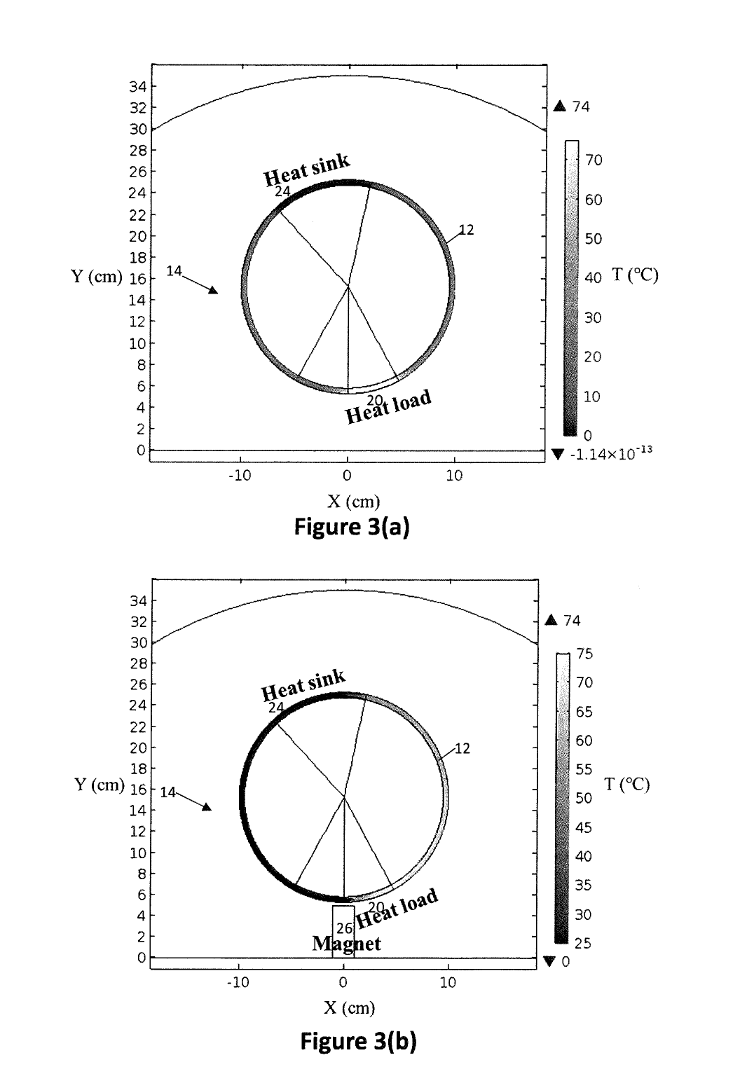

FIGS. 3(a) and 3(b) show schematics of a 2D model of the apparatus 10 of FIG. 2 showing temperature distribution of the ferrofluid 14, respectively, without and with an applied magnetic field. When there is no magnetic field applied (FIG. 3(a)), the ferrofluid is stationary and the thermal distribution is hottest adjacent the heat source 20 and coolest adjacent the heat sink 24 with a gradual temperature gradient therebetween in both arms of the conduit 12 loop.

When a magnetic field is applied (FIG. 3(b)) by the magnetic element 26, the temperature distribution changes and it is apparent that the ferrofluid 14 begins to flow around the conduit 12 because the heat from the heat source 20 extends in an anti-clockwise direction around the conduit 12 towards the heat sink 22 before the ferrofluid 14 gradually cools in the region of the heat sink 24. Cold ferrofluid 14 then flows on towards the heat source 20 before it is rapidly heated close to the heat source 20 before flowing once again towards the heat sink 24. Accordingly, it is concluded that the driving force for flow of the ferrofluid 14 is both magnetic and thermal.

Notably, placing the magnetic element 26 upstream of and adjacent to the heat source 20 means that the ferrofluid 14 further upstream of the magnetic element 26 will be relatively cool (and therefore more magnetised) and the ferrofluid 14 downstream of the magnetic element 26 will be relatively hot (and therefore less magnetised) due to the presence of the heat source 20 and this temperature gradient will help to drive the flow of the ferrofluid 14 in the direction of the heat source 20 (since the more magnetised cool ferrofluid 14 will have a stronger attraction to the magnetic field than the less magnetised hot ferrofluid 14).

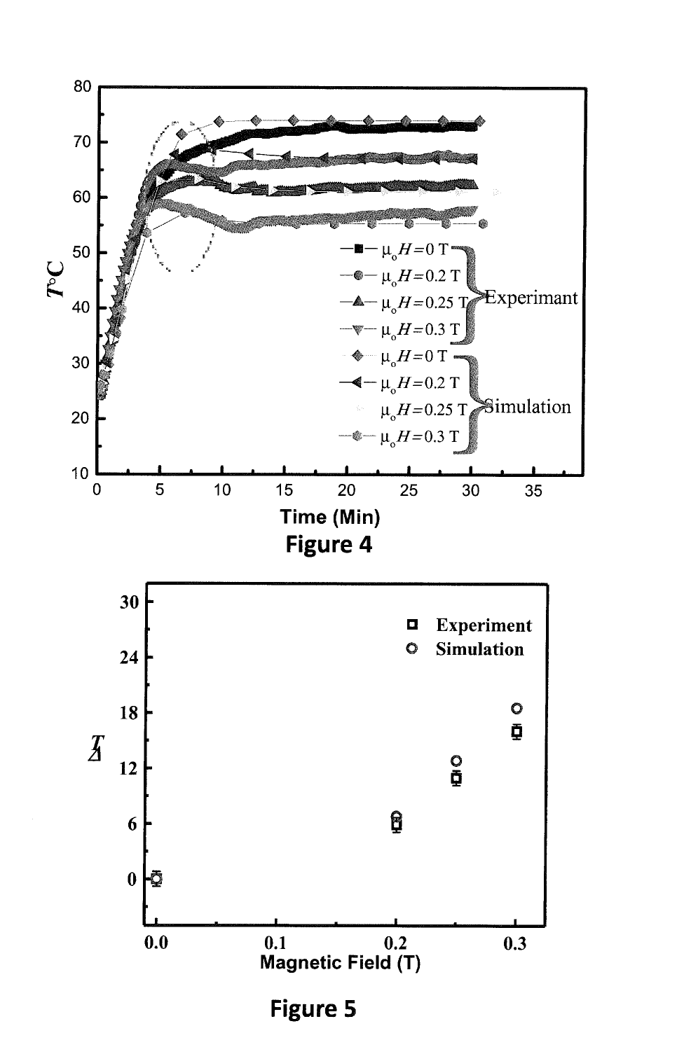

FIG. 4 shows a graph of temperature against time for various magnetic fields (T=0, 0.2, 0.25, 0.3) when applied to the apparatus 10 of FIG. 2, both by experiment and simulation using the model outlined above. In this embodiment, the heat source 20 was provided with a heat load of 4.4 W which corresponded to an initial temperature of 74° C. with no magnetic field applied. In this embodiment, the magnetic field strength was varied by changing the distance between the magnetic element 26 and the conduit 12.

In all cases, the temperature of the ferrofluid 14 increased during approximately the first 5 minutes and thereafter the temperature levelled off but the value at which the temperature levelled off was different depending on the magnetic field. As expected, the highest temperature (of about 74° C.) was recorded for the case where no magnetic field was applied and therefore no cooling was induced. When a magnetic field of 0.2 T was applied the temperature plateaued at about 65° C., when a magnetic field of 0.25 T was applied the temperature plateaued at about 60° C., and a magnetic field of 0.3 T was applied the temperature plateaued at about 55° C. In all cases, the experimental results corresponded well with the simulated results.

From the above it is evident that the temperature of the heat source 20 drops with increasing magnetic field, which indicates that thermomagnetic convection, induced by the magnetic field, increases with increasing magnetic field. The combination of a temperature gradient and an applied magnetic field, thus, results in thermomagnetic convection.

As explained earlier, the magnetisation of the ferrofluid 14 decreases with increasing temperature such that the ferrofluid 14 in the first portion 18 of the conduit 12 (adjacent the heat source 20) possesses less magnetisation than in other portions of the conduit 12. Also, the magnetisation of the magnetic nanoparticles increases with increasing magnetic field. Accordingly, the volume force (F_{M}) depends directly on the applied magnetic field and therefore a higher magnetic field results in a larger amount of cooling. In both the experiments and the simulation, with non-zero magnetic field, the temperature profiles exhibit transient behavior (marked by an ellipse in FIG. 4). This behavior can be understood by the fact that the cold ferrofluid 14 from the second portion 22 near the heat sink 24 has not reached the hot first portion 18 of the conduit 12 by that time. Once the ferrofluid 14 from cold second portion 22 reaches the magnetic element 26 (and is therefore near the heat source 20), the temperature gradient increases, which results in greater thermomagnetic convection.

The temperature difference (of the heat source 20) after 25 minutes, for both experiments and simulation, are plotted in FIG. 5. These also conclude that a greater temperature difference (i.e. a greater amount of cooling) can be achieved using a higher magnetic field strength.

### Effect of Load Temperature

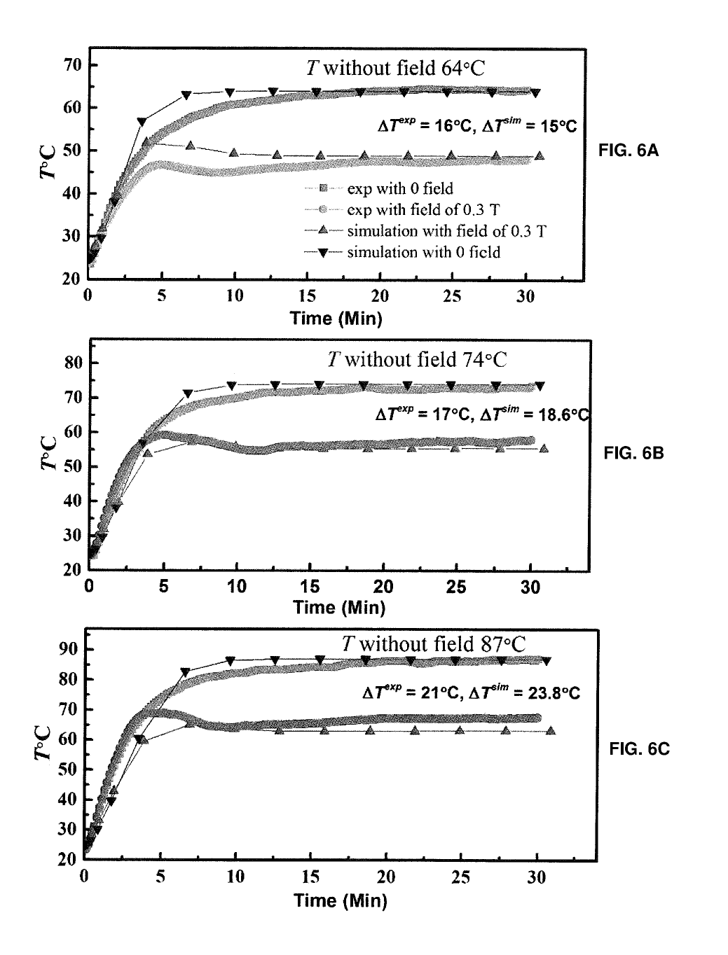

FIGS. 6A, 6B, and 6C show heat load temperatures against time for an initial temperature of (a) 64° C., (b) 74° C. and (c) 87° C., respectively, without and with a magnetic field of 0.3 T. The experiment results and simulated results show good correlation and a clear temperature reduction was observed in each case, when the magnetic field was applied.

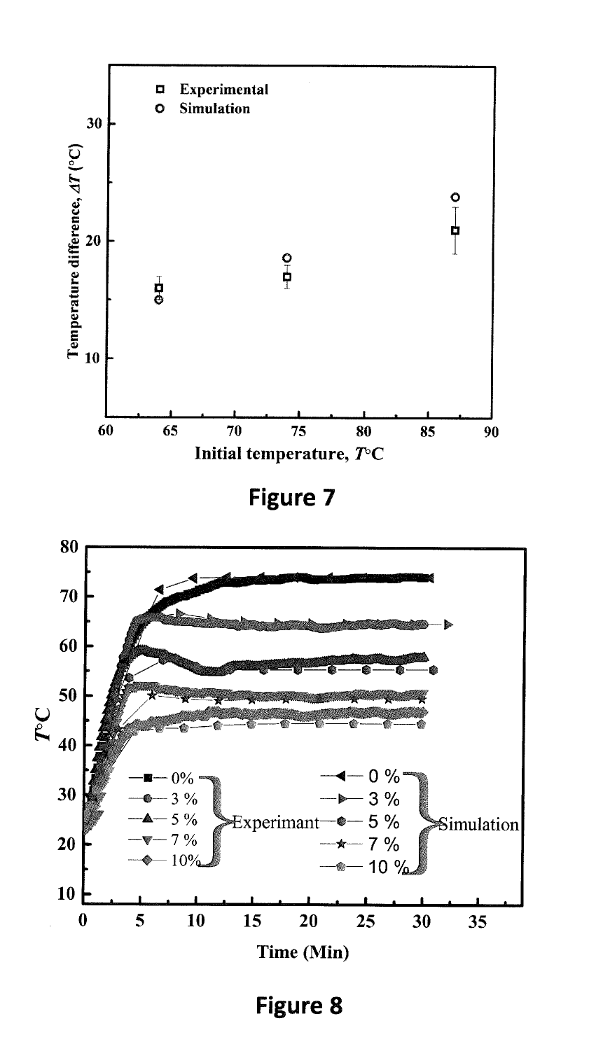

More specifically, for an initial temperature of 64° C., a reduction of 16° C. was observed through experiment (17° C. through simulation). For an initial temperature of 74° C., a reduction of 17° C. was observed through experiment (18.6° C. through simulation). For an initial temperature of 87° C., a reduction of 21° C. was observed through experiment (23.8° C. through simulation). FIG. 7 shows the temperature difference of the heat sources 20 of FIG. 6 with and without the applied magnetic field, for the different initial temperatures.

Thus, both the experimental and simulated results indicate greater cooling with higher initial temperature. Accordingly, such apparatus in accordance with embodiments of the invention possess an attractive self-pumping and regulating feature. However, the temperature limit of such an apparatus will be limited to the boiling temperature of the ferrofluid 14.

### Effect of Fluid Concentration

To examine the effect of volume fraction of the magnetic nanoparticles, ferrofluids 14 with 0%, 3%, 5%, 7% and 10% of magnetic nanoparticles were prepared in water and an initial temperature of the heat source 20 was selected to be 74° C.

FIG. 8 shows the effect of the nanoparticle content on the cooling of the heat source 20 with time. As the nanoparticle content increases, the amount of cooling also increases. However, the assumption that the nanoparticles do not aggregate becomes less valid, weakening the agreement between experiment and simulation. For a high volume concentration, the magnetic nanoparticles start to settle in the presence of the applied magnetic field and this reduces the velocity of the ferrofluid 14 and therefore results in less cooling than would otherwise be expected.

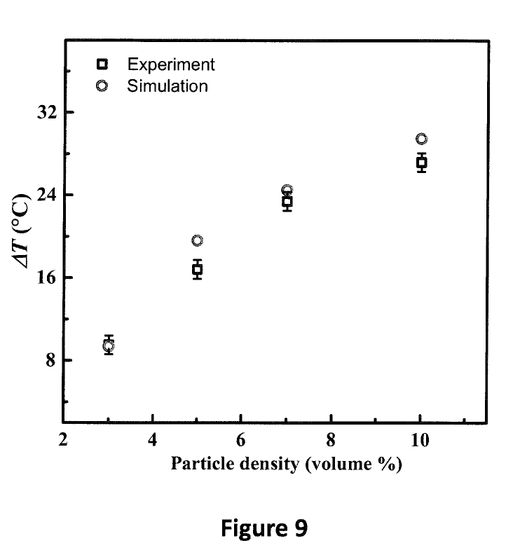

FIG. 9 shows the temperature difference of the heat source 20 for the different volume fractions of magnetic nanoparticles, which, again shows an increasing temperature difference with increasing volume fraction.

### Switching (‘0’ and ‘1’) of Magnetic Field

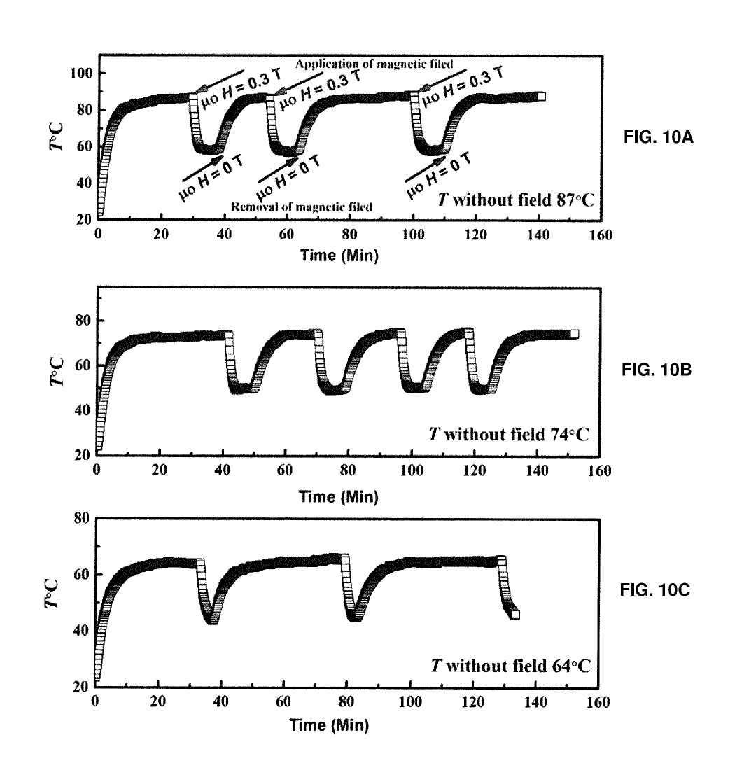

FIGS. 10A, 10B, and 10C show temperatures against time graphs for an initial temperature of a heat load of (a) 87° C., (b) 74° C. and (c) 64° C., respectively, showing the effect of application and removal of a magnetic field of 0.3 T.

In FIG. 10(a), after reaching a steady state of 87° C., the magnetic field was applied after about 30 minutes and the temperature quickly dropped (within a few minutes) to a steady cooled temperature of approximately 59° C. The magnetic field was removed after about 40 minutes and the temperature quickly rose to its steady state value of 87° C. After 50 minutes the magnetic field was applied and the temperature quickly dropped again to a steady cooled temperature of approximately 59° C. At about 60 minutes the magnetic field was removed and the temperature quickly rose back to its steady state value of 87° C. At about 100 minutes the magnetic field was applied and the temperature quickly dropped again to a steady cooled temperature of approximately 59° C. At about 110 minutes the magnetic field was removed and the temperature quickly rose back to its steady state value of 87° C.

In FIG. 10(b), after reaching a steady state of 74° C., the magnetic field was applied after about 40 minutes and the temperature quickly dropped (within a few minutes) to a steady cooled temperature of approximately 50° C. The magnetic field was removed after about 50 minutes and the temperature quickly rose to its steady state value of 74° C. After 70 minutes the magnetic field was applied and the temperature quickly dropped again to a steady cooled temperature of approximately 50° C. At about 80 minutes the magnetic field was removed and the temperature quickly rose back to its steady state value of 74° C. At about 95 minutes the magnetic field was applied and the temperature quickly dropped again to a steady cooled temperature of approximately 50° C. At about 105 minutes the magnetic field was removed and the temperature quickly rose back to its steady state value of 74° C. At about 115 minutes the magnetic field was applied and the temperature quickly dropped again to a steady cooled temperature of approximately 50° C. At about 125 minutes the magnetic field was removed and the temperature quickly rose back to its steady state value of 74° C.

In FIG. 10(c), after reaching a steady state of 64° C., the magnetic field was applied after about 30 minutes and the temperature quickly dropped (within a few minutes) to a steady cooled temperature of approximately 44° C. The magnetic field was removed after about 35 minutes and the temperature quickly rose to its steady state value of 64° C. After 75 minutes the magnetic field was applied and the temperature quickly dropped again to a steady cooled temperature of approximately 44° C. At about 80 minutes the magnetic field was removed and the temperature quickly rose back to its steady state value of 64° C. At about 125 minutes the magnetic field was applied and the temperature quickly dropped again to a steady cooled temperature of approximately 44° C.

In all cases, after applying the magnetic field, a quick drop in temperature was observed. The temperature drop (cooling) in (a), (b) and (c) was approximately 28° C., 24° C. and 20° C., respectively. Interestingly, the temperature drop in every cycle was almost constant for every fixed initial temperature. When the magnetic field was removed, the temperature of heat source 20 again increased to the initial temperature and the steady state was obtained. The cooling (ΔT) increased from ˜20° C. to ˜28° C., when the initial temperature of the heat source 20 was changed from 64° C. to 87° C. Importantly, the cooling is relatively fast with the change in temperature occurring within 2 to 3 minutes. Hence, it has been demonstrated that pumping and cooling can be controlled by the application or removal the magnetic field.

However, the performance of apparatus according to embodiments of the invention depends on a number of parameters. These parameters are not limited to a specific composition of nanoparticles, the strength of the magnetic field, the magnetic fluid concentration and base fluid properties. In addition, the size and shape of the apparatus 10, conduit 12 materials and its properties, the size and temperature of the heat sink 24 and the physical properties of the heat sink 24 may all need to be adjusted according to a particular application.

### Shape Effect

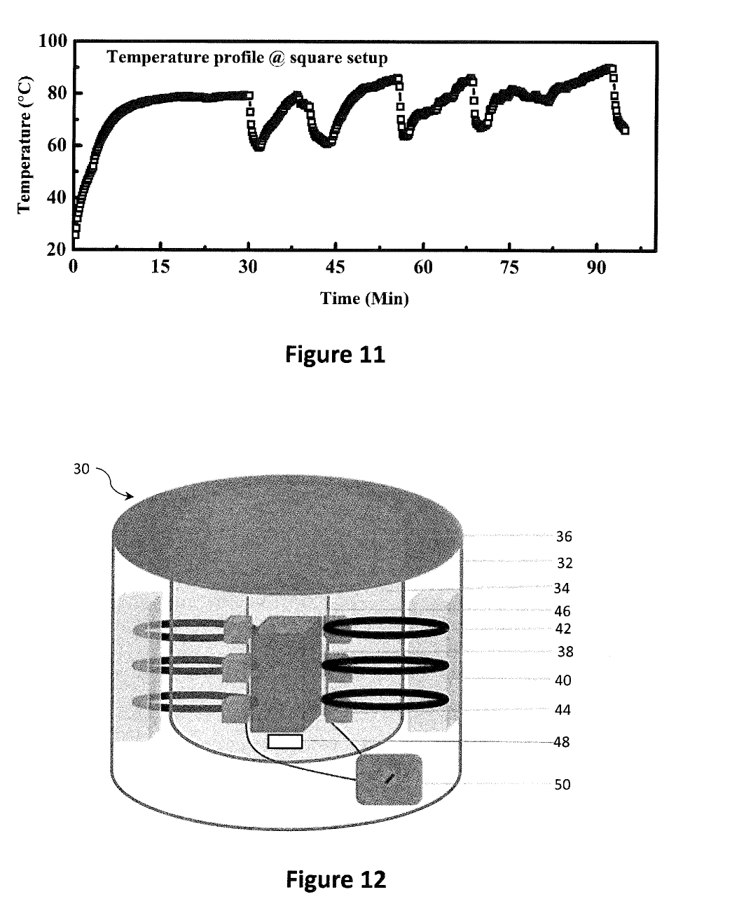

FIG. 11 shows a temperature against time graph for a heat source 20, showing the effect of application and removal of a magnetic field of 0.3 T when a square cross-section conduit 12 is employed. In this embodiment, the conduit 12 had the same length and diameter as the circular conduit used in the experiments above and all other parameters remained the same.

In this case, the initial temperature without the magnetic field was fixed at 78° C. and after achieving a steady state, a magnetic field of 0.3 T was applied. After applying this magnetic field, a quick drop in temperature similar to that in the circular setup was observed. However, in this instance, the temperature drop every time the magnetic field is applied varies, unlike for the circular conduit. Also, when the magnetic field is not applied, the steady state temperature in this set-up is not constant and increases from 78° C. to 88° C.

These results suggest that magnetic cooling can be achieved using a square-shaped conduit but that a circular shape is better to obtain a more controlled and larger cooling effect.

It is believed that the cooling performance of the apparatus was reduced in this instance because a boundary condition is different at the corners of the square cross-section of the conduit.

In addition to the shape of the conduit 12, the material of the conduit 12 may be changed to suit a particular application. For example, the conduit may comprise copper, quartz, plastic etc. However, it will be understood that a material that is a good thermal conductor is desirable.

### Heat Sink

Experiments were conducted for different positions of the heat sink 24 and it was determined that locating the heat sink 24 opposite to the heat source 20 gave the best performance.

It was also determined that a decrease in the size of the heat sink 24 will decrease performance by decreasing the observed change in temperature ΔT.

If the heat source 20 temperature is greater than room/ambient temperature, then the proposed cooling apparatus will work even without a heat sink 24 (i.e. wherein the heat sink is effectively room/ambient temperature). However, in this case the observed change in temperature ΔT will be less than the value obtainable with a heat sink 24 of a lower than room/ambient temperature.

In practice, the heat sink 24 can be chosen to provide the required cooling temperature and the heat sink 24 temperature can vary depending on the cooling medium used (e.g. air, water, sea, ice, dry ice or another fluid).

### Base Fluid

A water-based ferrofluid 14 can be used only up to the boiling temperature of water. If the heat source 20 temperature is higher than the boiling temperature of water, the magnetic nanoparticles should be dispersed in another fluid which has a higher boiling temperature (e.g. kerosene, amines etc.).

Low density fluid is believed to provide better cooling as it is less viscous and flows more easily.

### Type of Magnet

The magnetic element 26 may be in the form of a permanent magnet as described above or may comprise an electromagnet (having a solenoid through which current is passed to generate a magnetic field).

The size of the magnetic element 26 and therefore the size of the section of the conduit 12 exposed to the magnetic field will also influence the amount of cooling by the apparatus.

### Apparatus Configuration

FIG. 12 shows an apparatus 30 according to an embodiment of the invention in which six circular conduits are employed for a cold chain storage application (e.g. to cool food, drink or vaccines. The apparatus 30 comprises an outer cylindrical container 32 and a concentric inner cylindrical container 34. A lid 36 covers both the inner container 34 and the outer container 36. A heat source 38 is provided in the centre of the inner container 34. In use, the heat source may be constituted by food, drink or a vaccine. Two heat sinks 40 are provided at opposed sides of the outer container 36.

Six circular loop conduits 42 containing ferrofluid (including a plurality of magnetic nanoparticles as described above) are provided, three of which are positioned in a spaced and horizontally stacked arrangement on opposite sides of the heat source 38 such that they each have a first inner portion thermally coupled to the heat source 38 and a second outer portion thermally coupled to one of the heat sinks 40.

Six magnetic elements 44 are arranged to provide a magnetic field to the ferrofluid in each of the six conduits 42 and are located upstream of the first inner portions of each conduit 42 to drive a flow of the ferrofluid in the direction of the heat source 38. The magnetic elements 44 are in the form of permanent magnets positioned close to an upstream end of the heat source 38. Each of the magnetic elements 44 is mounted on a stage 46 which is configured to move the magnetic elements 44 either closer towards the first inner portions of the conduits 42 or further away therefrom to vary the magnetic field on the ferrofluid within the conduits 42.

A thermocouple 48 is located close to the heat source 38 and is arranged to drive a control system 50 to move the stage 46 to adjust the position of the magnetic elements 44 relative to the conduits 42 to vary the amount of cooling. The control system 50 may be configured to maintain the heat source 38 within a desired temperature range. If the temperature measured by the thermocouple 48 deviates from the desired temperature range, the stage 46 will automatically move the magnetic elements 44 closer to or further away from the conduits 42 to alter the amount of cooling. To increase the cooling, the magnetic elements 44 will be moved closer to the conduits 42, on the other hand, to decrease the cooling, the magnetic elements 44 will be moved away from the conduits 42. By changing the distance of the magnetic elements 44 from the conduits 42 the effective magnetic field on the ferrofluid within each conduit 42 is changed and therefore the flow rate of the ferrofluid is also changed thereby altering the amount of cooling.

There are many objects which need to be maintained at a particular temperature and for which cooling to lower temperatures may be disadvantageous. The present embodiment can therefore be employed to control the temperature of such objects within an acceptable temperature window.

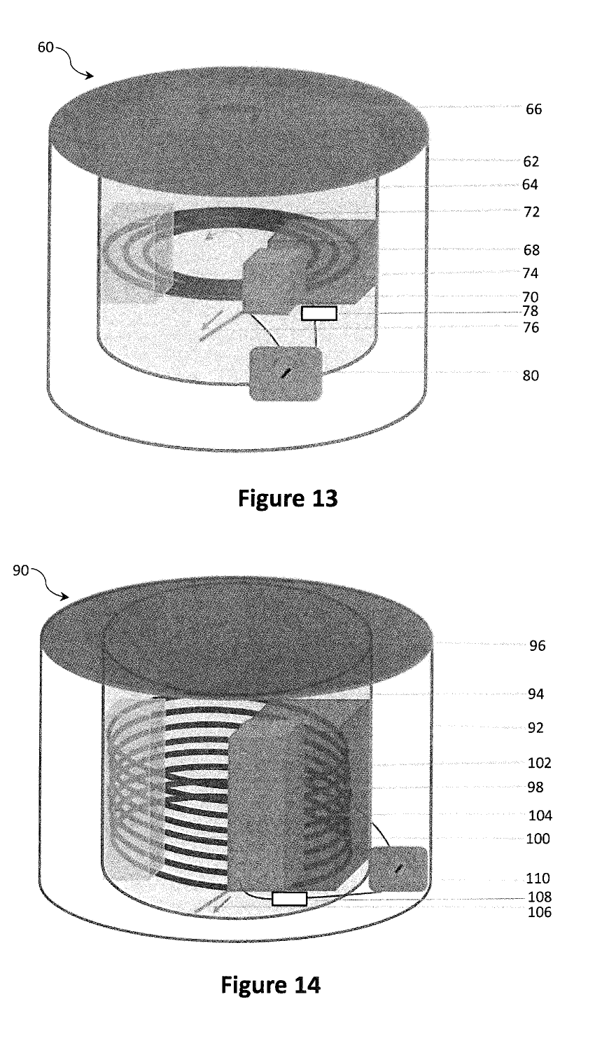

Furthermore, instead of the stacked circular conduit set-up of FIG. 12, it is possible to use concentric circular (or other shaped) conduits or a spiral or helical conduit for magnetic cooling. The shape of the conduit can be chosen according to the size of the heat source and the cooling requirements. Embodiments employing concentric circular conduits and a helical shaped conduit suitable for a cold chain storage application are shown in FIGS. 13 and 14, respectively.

More specifically, FIG. 13 shows an apparatus 60 according to an embodiment of the invention in which three concentric conduits are employed for a cold chain storage application. The apparatus 60 comprises an outer cylindrical container 62 and a concentric inner cylindrical container 64. A lid 66 covers both the inner container 64 and the outer container 66. A heat source 68 is provided at one side of the inner container 64. In use, the heat source 68 may be constituted by food, drink or a vaccine. In this embodiment, a single heat sink 70 is provided at an opposite side of the inner container 64 from the heat source 68.

Three concentric circular loop conduits 72 containing ferrofluid (including a plurality of magnetic nanoparticles as described above) are provided. These are positioned in a spaced and horizontally concentric arrangement centred within the inner container 64 such that they each have a first portion thermally coupled to the heat source 68 and a second portion thermally coupled to the heat sink 70.

A single large magnetic element 74 is arranged to provide a magnetic field to the ferrofluid in each of the three conduits 72 and is located upstream of the first portions of each conduit 42 to drive a flow of the ferrofluid in the direction of the heat source 68. The magnetic element 74 is in the form of a permanent magnet positioned close to an upstream end of the heat source 68. The magnetic element 74 is mounted on a stage 76 which is configured to move the magnetic element 74 either closer towards the first portions of the conduits 72 or further away therefrom to vary the magnetic field on the ferrofluid within the conduits 72.

A thermocouple 78 is located close to the heat source 68 and is arranged to drive a control system 80 to move the stage 76 to adjust the position of the magnetic element 74 relative to the conduits 72 to vary the amount of cooling. The control system 80 may be configured to maintain the heat source 68 within a desired temperature range. If the temperature measured by the thermocouple 78 deviates from the desired temperature range, the stage 76 will automatically move the magnetic element 74 closer to or further away from the conduits 72 to alter the amount of cooling. To increase the cooling, the magnetic element 74 will be moved closer to the conduits 72, on the other hand, to decrease the cooling, the magnetic element 74 will be moved away from the conduits 72. By changing the distance of the magnetic element 74 from the conduits 72 the effective magnetic field on the ferrofluid within each conduit 72 is changed and therefore the flow rate of the ferrofluid is also changed thereby altering the amount of cooling.

FIG. 14 shows an apparatus 90 according to an embodiment of the invention in which a single helical conduit (containing multiple windings) is employed for a cold chain storage application. The apparatus 90 comprises an outer cylindrical container 92 and a concentric inner cylindrical container 94. A lid 96 covers both the inner container 94 and the outer container 96. A heat source 98 is provided at one side of the inner container 94. In use, the heat source 98 may be constituted by food, drink or a vaccine. In this embodiment, a single heat sink 100 is provided at an opposite side of the inner container 94 from the heat source 98.

A single helical loop conduit 102 containing ferrofluid (including a plurality of magnetic nanoparticles as described above) is provided. The conduit 102 is positioned centrally within the inner container 94 such that first portions of the multiple windings of the conduit 102 are thermally coupled to the heat source 98 and second portions of the multiple windings of the conduit 102 are thermally coupled to the heat sink 100.

A single large magnetic element 104 is arranged to provide a magnetic field to the ferrofluid in each of the windings of the conduit 102 and is located upstream of the first portions of each winding to drive a flow of the ferrofluid in the direction of the heat source 98. The magnetic element 104 is in the form of a permanent magnet positioned close to an upstream end of the heat source 98. The magnetic element 104 is mounted on a stage 106 which is configured to move the magnetic element 104 either closer towards the first portions of the conduit 102 or further away therefrom to vary the magnetic field on the ferrofluid within the conduit 102.

A thermocouple 108 is located close to the heat source 98 and is arranged to drive a control system 110 to move the stage 106 to adjust the position of the magnetic element 104 relative to the conduit 102 to vary the amount of cooling. The control system 110 may be configured to maintain the heat source 98 within a desired temperature range. If the temperature measured by the thermocouple 108 deviates from the desired temperature range, the stage 106 will automatically move the magnetic element 104 closer to or further away from the conduit 102 to alter the amount of cooling. To increase the cooling, the magnetic element 104 will be moved closer to the conduit 102, on the other hand, to decrease the cooling, the magnetic element 104 will be moved away from the conduit 102. By changing the distance of the magnetic element 104 from the conduit 102 the effective magnetic field on the ferrofluid within each winding of the conduit 102 is changed and therefore the flow rate of the ferrofluid is also changed thereby altering the amount of cooling.

### Applications

It will be understood that apparatus according to embodiments of the invention may be configured for many different uses and for cooling for a range of different heat source temperatures.

Conventional electronic components are designed to operate over a specified temperature range with upper limits generally set at 70° C. for commercial applications, 85° C. for industrial applications, and 125° C. for military applications. An increase in temperature beyond the upper limit of an electronic device is a major cause of electronic failure.

An apparatus as described above in accordance with any of the embodiments above may be used with a ferrofluid containing Mn_{0.4}Zn_{0.6}Fe₂O₄ magnetic nanoparticles dispersed in water would be suitable to cool the electronic devices for commercial and industrial applications since these have been demonstrated to cool from 87° C. to below 50° C.

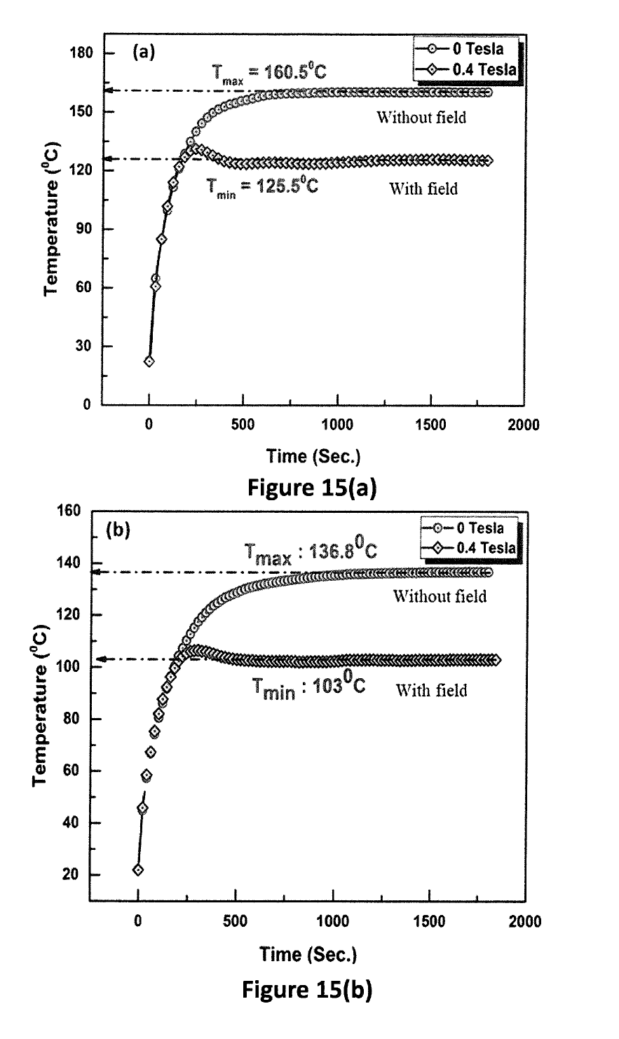

Furthermore, an apparatus as described above in accordance with any of the embodiments above may be used with a ferrofluid containing Fe₃O₄ nanoparticles dispersed in oil to cool an electronic device for a military application from 160° C. to below 110° C. For example, FIGS. 15A and 15B show temperatures against time graphs for such an apparatus for an initial temperature of a heat load of (a) 160.5° C. and (b) 136.8° C., respectively, showing the effect of application and removal of a magnetic field of 0.4 T. Thus, it can be seen that with the application of the magnetic field, the temperature of (a) can be reduced to 125.5° C. and the temperature of (b) can be reduced to 103° C.

In addition, it has been found that an apparatus as described above in accordance with any of the embodiments above may be used with a ferrofluid containing (Fe₇₀Ni₃₀)₁₀₀₋ₓCrₓ (where x=1 to 3) magnetic nanoparticles to cool a heat source from above 165° C. to below room temperature.

However, the application of embodiments of the invention are not limited to the cooling of electronic devices. On the contrary, embodiments of the invention have the potential to cool any object with appropriate design of the apparatus and selection of a suitable ferrofluid.

For example, Mn_{0.3}Zn_{0.7}Fe₂O₄ magnetic nanoparticles are suitable for use in apparatus according to embodiments of the invention if the heat source temperature is in the range of 5 to 15° C. Accordingly, a 5% concentration of such magnetic nanoparticles, coated with oleic acid in an aqueous medium can be employed for cold chain storage.

Also, (Fe₇₀Ni₃₀)₁₀₀₋ₓCrₓ, where x is from 0 to 7.0 (e.g. from 0.1 to 7.0) magnetic nanoparticles having a Curie temperature of from 125° C. to −58° C. are suitable for use in apparatus according to embodiments of the invention for from above room temperature to below room temperature applications. A particular type of this nanoparticle that may be mentioned herein are (Fe₇₀Ni₃₀)₉₅Cr₅ magnetic nanoparticles that have a Curie temperature of −15° C., which are suitable for use in apparatus according to embodiments of the invention for below room temperature applications such as cold chain storage and vaccine cooling.

In general, apparatus according to embodiments of the invention may be configured for cooling applications in electronic devices, lasers, laptops, computers, solar panels, buildings, vehicles (including automobiles, airplanes, spacecraft and ships), cold chain storage (e.g. for food or drink) and medical applications (e.g. for vaccine storage).

It is also noted that apparatus according to embodiments of the invention are particularly useful for applications where maintenance is difficult, such as in spacecraft or satellites because an external pump (having moving mechanical parts) is not required. Furthermore, embodiments of the invention could be used to overcome recent problems due to overheating of solar panels by effectively controlling excessive temperature. In addition, embodiments of the invention could be used, for example, to cool engines in ships, whereby waste heat from the engine will constitute the heat source and sea water may constitute the heat sink.

### Summary

Embodiments of the invention utilise a magneto-thermal force for pumping fluids to cool objects. It has been observed that magnetic nanoparticles dispersed in a ferrofluid change their magnetisation at high temperatures and the thermomagnetic convection for different initial temperatures and applied magnetic fields have been characterised. It has been demonstrated the combination of waste heat and applied magnetic field drive the ferrofluid in a self-regulating manner to transfer the waste heat to heat sink. It has also been found that locating the magnetic element upstream of the heat source provides the most effective driving force.

It will be noted that in embodiments of the apparatus many parameters may be varied to suit a particular temperature cooling requirement or application. For example, the type and concentration of magnetic nanoparticles, the type of base fluid for the ferrofluid, the number, size, shape and arrangement of the conduits, the properties of the heat sink and the magnetic field strength of the magnetic element may all be selected for a particular application.

Embodiments of the invention are believed to be energy efficient, cost-effective, reliable, portable and environmentally friendly, without requiring an external pump (causing vibration and noise) and without compromising on speed, effectiveness, quality and safety.

Further information relating to embodiments of the invention can be found in the following publications, incorporated herein by reference:
1. V. Chaudhary & R. V. Ramanujan “Magnetocaloric Properties of Fe—Ni—Cr Nanoparticles for Active Cooling” Scientific Reports, 11 Oct. 2016;
2. V. Chaudhary, Z Wang, A Ray, I Sridhar & R. V. Ramanujan “Self-pumping Magnetic Cooling” Journal of Physics D: Applied Physics 50 (2017) 03LT03;
3. V Sharma, D. V. Maheshwar Repaka, V. Chaudhary & R. V. Ramanujan “Enhanced magnetocaloric properties and critical behaviour of (Fe_{0.72}Cr_{0.28})₃Al alloys for near room temperature cooling” Journal of Physics D: Applied Physics 50 (2017) 145001.

### Fe—Ni—Cr Nanoparticles for Active Cooling

Energy efficient magnetocaloric materials for magnetic cooling have attracted intense research interest due to unsustainable energy consumption and limitations of current cooling technologies. A well-known milestone in magnetic cooling was the development of a compressor free wine cooler based on magnetic cooling, developed by Haier, BASF and Astronautics Corporation. Magnetic cooling is potentially very environmentally friendly because it has already been shown to use 35% less power than conventional cooling and it does not use ozone layer depleting hydrofluorocarbons. In addition, magnetic cooling is also a low noise and low vibration technology, which is a further significant advantage over conventional technologies.

The magnetocaloric effect (MCE) is the change in temperature of a material due to the adiabatic application or removal of an external magnetic field. This temperature change is related to the magnetic entropy change (ΔS_{M}). Generally, MCE is large in the vicinity of the Curie temperature (T_{C}), where the magnetic spins undergo an order-disorder phase transition.

Typically, bulk magnetocaloric materials have been developed for cooling systems. The magnetocaloric effect in nanostructured materials has received considerable interest recently because they possess additional advantages. These nanomaterials can be useful for active magnetic cooling devices, microfluidic reactors and other systems. Slow heat transfer in bulk solids is one of the most difficult issues which diminish the efficiency of thermal management systems. The dispersion of magnetic nanoparticles in a suitable fluid can solve this challenge, as the large surface area of nanoparticles and their dispersion in fluid results in better thermal contact, and therefore faster heat exchange, compared to bulk systems. Furthermore, such ferrofluids can be used for self-pumping, automatic magnetic cooling.

### Summary of Invention for Fe—Ni—Cr Nanoparticles

In an aspect of the invention, there is provided, a composition comprising nanoparticles of the formula (Fe₇₀Ni₃₀)₁₀₀₋ₓCrₓ, where x is from 0 to 7.0.

Embodiments of this aspect may include compositions where:

(a) x may be from 0.5 to 7.0, such as from 2.5 to 5.5, such as 5.0;

(b) the nanoparticles may have an average particle size of from 5 nm to 20 nm, such as from 8 nm to 15 nm, optionally wherein the nanoparticles have an average particle size of from 9 nm to 13 nm;

(c) the nanoparticles may be coated with a coating material, which coating material may, in certain embodiments, be selected from one or more of the group consisting of oleic acid, ammonium hydroxide, inorganic oxides, and polymeric materials, optionally wherein the coating material contains from oleic acid and ammonium hydroxide (e.g. the coating material may contain from 50 to 95 wt % oleic acid and from 5 to 50 wt % ammonium hydroxide, such as from 70 to 85 wt % oleic acid and from 15 to 30 wt % ammonium hydroxide, optionally wherein the coating material contains 80 wt % oleic acid and 20 wt % ammonium hydroxide);

(d) when a coating material is present, the wt:wt amount of the coating material relative to the nanoparticles may be from 1:9 to 1:1 and/or the coated nanoparticles have an average particle size of from 10 nm to 30 nm, such as from 15 nm to 25 nm.

Compositions of the formula (Fe₇₀Ni₃₀)₁₀₀₋ₓCrₓ mentioned herein may have one or more of the following properties:

(a) a Curie Temperature of from 215 to 398 K when subjected to an applied magnetic field (μₒH) of 5 T; and/or

(b) a magnetic entropy of from 1.11 to 1.58 J/kgK when subjected to an applied magnetic field (μₒH) of 5 T; and/or

(c) a relative cooling power of from 306 to 548 J/kg when subjected to an applied magnetic field (μₒH) of 5 T.

Compositions of the formula (Fe₇₀Ni₃₀)₁₀₀₋ₓCrₓ may be particularly suited for use in magnetic cooling. Thus, in a further aspect of the invention, there is provided a ferrofluid comprising:

a liquid carrier; and

nanoparticles coated with a coating material, wherein the nanoparticles have the formula (Fe₇₀Ni₃₀)₁₀₀₋ₓCrₓ, where x is from 0 to 7.0.

It will be appreciated that the nanoparticles of the formula (Fe₇₀Ni₃₀)₁₀₀₋ₓCrₓ as disclosed hereinabove may use the same coating materials and may have the same properties as described above.

Suitable liquid carriers may be selected from one or more of the group consisting of oleic acid, silicone oil, oleyl-amin, octadecane, and water.

In the ferrofluid, the coated nanoparticles may be present in an amount of from 1 to 8 vol % in the ferrofluid. For example, from 3 to 5 vol % of the ferrofluid, such as 5 vol %.

In yet a further aspect of the invention, nanoparticles having the formula (Fe₇₀Ni₃₀)₁₀₀₋ₓCrₓ may be prepared by a method comprising the step of high energy ball milling elemental iron, nickel and chromium together in a suitable weight:weight ratio to provide nanoparticles having the formula (Fe₇₀Ni₃₀)₁₀₀₋ₓCrₓ, where x is from 0 to 7. Said method may also comprise a further step of coating the nanoparticles with a coating material mentioned hereinbefore.

It will be appreciated that nanoparticles of the formula (Fe₇₀Ni₃₀)₁₀₀₋ₓCrₓ or a ferrofluid containing the same may, in yet further aspects of the invention, be used in magnetic cooling.

### Description for Fe—Ni—Cr Nanoparticles

The effect of alloying Fe₇₀Ni₃₀ with Cr on magnetic phase transition temperature (T_{C}) and magnetocaloric properties of alloy nanoparticles has been investigated and has been shown to provide a number of advantages over other materials. In particular, the iron-nickel-chromium nanoparticles surprisingly maintain useful magnetic properties over a wide range of Curie temperatures, while being relatively inexpensive to manufacture. In addition, it is believed that the use of chromium may improve the corrosion-resistance of the nanoparticles disclosed herein.

Thus, there is provided a composition comprising nanoparticles of the formula (Fe₇₀Ni₃₀)₁₀₀₋ₓCrₓ, where x is from 0 to 7.0.

The numbers 70, 30, 100−x and x when used in the above-mentioned formula refer to weight percentages. Thus, “Fe₇₀Ni₃₀” refers to the use of 70 wt % elemental iron relative to 30 wt % elemental nickel in all compositions used herein. As dictated by the above-mentioned formula, the actual amount of iron and nickel with respect to chromium in compositions of the current formula will depend on the amount of chromium present in the composition. For example, in a composition having the formula (Fe₇₀Ni₃₀)₉₉Cr₁, there is provided 69.3 wt % of elemental iron, 29.7 wt % of elemental nickel (maintaining a 70 wt % iron relative to 30 wt % nickel) and 1 wt % of elemental chromium.

As noted above, chromium may form from 0 wt % to 7.0 wt % of the nanoparticles when taken together with the amount of iron and nickel only. While the six compositions disclosed herein: Fe₇₀Ni₃₀, (Fe₇₀Ni₃₀)₉₉Cr₁, (Fe₇₀Ni₃₀)₉₇Cr₃, (Fe₇₀Ni₃₀)₉₅Cr₅, (Fe₇₀Ni₃₀)₉₄Cr₆, and (Fe₇₀Ni₃₀)₉₃Cr₇, referred to herein as Cr0, Cr1, Cr3, Cr5, Cr6 and Cr7, respectively, make use of an integer value for “x”, fractional values may also be used. For example, “x” may be 0.5, 0.7, 1.25, 3.5, 4.6 and the like.

Suitable values for x may be from 0.5 to 7.0 (e.g. from 1.0 to 7.0), such as from 2.5 to 5.5, such as 5.0.

As disclosed in the experimental section below, the nanoparticles of the current application may have properties that are comparable to, or better than, other nanoparticles that may be suitable for use in magnetic cooling applications. In particular, the nanoparticles disclosed herein may have:

(a) the nanoparticles have a Curie Temperature of from 215 to 398 K when subjected to an applied magnetic field (μₒH) of 5 T; and/or

(b) the nanoparticles have a magnetic entropy of from 1.11 to 1.58 J/kgK when subjected to an applied magnetic field (μₒH) of 5 T; and/or

(c) the nanoparticles have a relative cooling power of from 306 to 548 J/kg when subjected to an applied magnetic field (μₒH) of 5 T.

The nanoparticles having the formula (Fe₇₀Ni₃₀)₁₀₀₋ₓCrₓ may have an average particle size of from 5 nm to 20 nm, such as from 8 nm to 15 nm. A particular average particle size that may be mentioned herein may be from 9 nm to 13 nm. Unless otherwise stated the average particle sizes may be estimated based on the x-ray diffraction patterns of the nanoparticles as calculated by the Scherrer formula after subtracting the instrumental line broadening. Additionally or alternatively, the average particle size may be calculated using bright field transmission electron micrography.

As discussed in more detail in the experimental section, the nanoparticles of (Fe₇₀Ni₃₀)₁₀₀₋ₓCrₓ disclosed herein (e.g. where x=1, 3, 5, 6 and 7) exhibits a second order magnetic phase transition that is tunable from ˜438 K to ˜215K (see Table 1 below). The wide Curie temperature distribution and therefore high RCP, is consistent with the asymmetric nature of the 111 diffraction peak in x-ray diffraction, which implies that the alloys exhibit a range of lattice parameters due to the process of ball milling. Without wishing to be bound by theory, this lattice distribution gives a high distribution of exchange interaction, which leads to a distribution of T_{C}. The reduction in T_{C} and ΔS_{M} with increasing Cr % is related to the reduction of total exchange energy due to the antiferromagnetic nature of Cr.

Engelbrecht et al. reported that for practical cooling systems, a material with a broad peak in entropy change (large δT_{FWHM}) provides significantly higher cooling power than a material with a sharp peak.²⁰ The cooling power for a material with low ΔS_{M} and high δT_{FWHM} is greater than that of a material with high ΔS_{M} and low δT_{FWHM}. Thus, for a magnetic regenerator, a broad temperature distribution of MCE is more attractive than sharp ΔS_{M} peaks.

One of the main factors that will enable or inhibit the commercial exploitation of a magnetic material is its cost. The cost of the disclosed materials (Cr1, Cr3, Cr5, Cr6 and Cr7) and other magnetocaloric materials were estimated based upon the cost of the pure elements used to manufacture said nanoparticles (see Table 1). The material cost of the Fe—Ni—Cr nanoparticles disclosed herein is only about 2% of the cost of pure Gd. Very recently, a transition metal based high entropy alloy NiFeCoCrPd_{X} was introduced as a promising magnetocaloric material. The material cost of the Fe—Ni—Cr disclosed herein is about 0.3% of the cost of NiFeCoCrPd_{0.50}. In addition, (Fe₇₀Ni₃₀)₉₅Cr₅ exhibits higher ΔS_{M} (123%) and RCP (180%) compared to NiFeCoCrPd_{0.25}, while the T_{C} is almost the same. Table 1 shows the values of ΔS_{M}, RCP and cost of the nanoparticulate alloys disclosed herein with respect to other magnetocaloric materials.

TABLE 1

| | | ΔS_{M} (J- | RCP (J- | Cost per | |
|---|---|---|---|---|---|
| Nominal | | kg⁻¹K⁻¹) | kg⁻¹) | 100 gm | |
| Composition | T_{c} (k) | (μₒH = 5T) | (μₒH = 5T) | ($) | Ref. |
| (Fe₇₀Ni₃₀)₉₉Cr₁ | 398 | 1.58 | 548 | 7.6 | Cr1 this |
| | | | | | work |
| (Fe₇₀Ni₃₀)₉₇Cr₃ | 323 | 1.49 | 436 | 8.1 | Cr3 this |
| | | | | | work |
| (Fe₇₀Ni₃₀)₉₅Cr₅ | 258 | 1.45 | 406 | 8.6 | Cr5 this |
| | | | | | work |
| (Fe₇₀Ni₃₀)₉₄Cr₆ | 245 | 1.22 | 366 | 8.8 | Cr6 this |
| | | | | | work |
| (Fe₇₀Ni₃₀)₉₃Cr₇ | 215 | 1.11 | 306 | 9.1 | Cr7 this |
| | | | | | work |
| NiFeCoCrPd_{0.25} | ~210 | 0.9/0.82 | 170/150 | 1526 | 21 |
| (as rolled/ | | | | | |
| annealed) | | | | | |
| NiFeCoCrPd_{0.50} | ~290 | 0.87/0.83 | — | 2984 | 21 |
| (as rolled/ | | | | | |
| annealed) | | | | | |
| (Fe₇₀Ni₃₀)₉₅Mn₅ | 338 | 1.45 | 470 | 7.3 | 17 |
| (Fe₇₀Ni₃₀)₉₂Mn₈ | 340 | 1.67 | 466 | 7.3 | 16 |
| (Fe₇₀Ni₃₀)₈₉Zr₇B₄ | 353 | 2.8 | 330 | 62.1 | 22 |
| (Fe₇₀Ni₃₀)₈₉B₁₁ | 381 | 2.1 | 640 | 129 | 4 |
| (Fe₇₀Ni₃₀)₉₆Mo₄ | 300 | 1.67 | 432 | 8.3 | 23 |
| Gd | 295 | 7.2 | ~400 | 450 | 24 |
| Gd₅Ge_{1.9}Si₂Fe_{0.1} | 300 | 7.1 | 630 | 409.4 | 25 |

As noted herein, the nanoparticles having the formula (Fe₇₀Ni₃₀)₁₀₀₋ₓCrₓ disclosed above may be particularly suitable for use in magnetic cooling and may therefore be used in the apparatus disclosed herein. As noted above, the nanoparticles may achieve more effective cooling when dispersed within a fluid. In order to provide a more effective dispersion within a fluid, the nanoparticles may be coated with a suitable coating material. Suitable coating materials that may be mentioned herein include, but are not limited to, oleic acid, ammonium hydroxide, inorganic oxides, polymeric materials and combinations thereof. In certain embodiments that may be mentioned herein, the coating material may contain oleic acid and ammonium hydroxide, for example the coating material may have from 50 to 95 wt % oleic acid and from 5 to 50 wt % ammonium hydroxide, such as from 70 to 85 wt % oleic acid and from 15 to 30 wt % ammonium hydroxide, (e.g. 80 wt % oleic acid and 20 wt % ammonium hydroxide).

When the nanoparticles are coated with a coating material, the wt:wt amount of coating material relative to the nanoparticles may be from 1:9 to 1:1. Coated nanoparticles may have an average particle size of from 10 nm to 30 nm, such as from 15 nm to 25 nm.

As noted above, in order to provide useful cooling effects, the nanoparticles of (Fe₇₀Ni₃₀)₁₀₀₋ₓCrₓ (whether coated or uncoated) may be dispersed within a fluid carrier to provide a ferrofluid. As such, the current invention also relates to the provision of a ferrofluid comprising a liquid carrier and nanoparticles having the formula (Fe₇₀Ni₃₀)₁₀₀₋ₓCrₓ, where x is from 0 to 7.0. In certain embodiments herein, the nanoparticles may be coated with a coating material as described hereinbefore.

As will be appreciated, the ferrofluid may make use of any suitable liquid carrier. Such carriers include, but are not limited to, oleic acid, silicone oil, oleyl-amin, octadecane, water and combinations thereof. It will be appreciated that the liquid carrier may contain additional components that may modify the properties of the carrier, for example to increase the boiling point, decrease the freezing point and/or modify the flow dynamics of the carrier. Suitable additives are well known.

Any suitable concentration of the nanoparticles disclosed herein in the liquid carrier may be used. For example, the liquid carrier may include from 1 to 8 vol % of the nanoparticles within the liquid carrier, such as from 3 to 5 vol % (e.g. 5 vol %).

The (Fe₇₀Ni₃₀)₁₀₀₋ₓCrₓ nanoparticles disclosed herein may be manufactured by any suitable method. One suitable method comprises the step of high energy ball milling elemental iron, nickel and chromium together in a suitable weight:weight ratio to provide nanoparticles having the formula (Fe₇₀Ni₃₀)₁₀₀₋ₓCrₓ, where x is from 0 to 7. It will be appreciated that “suitable weight ratio” means that the elemental starting materials are provided in amounts that provide the desired relative proportions of said elements in the final composition. In embodiments where the composition is coated the nanoparticles may be subjected to further high energy ball milling in the presence of one or more suitable coating materials.

It will be appreciated that the nanoparticles of formula (Fe₇₀Ni₃₀)₁₀₀₋ₓCrₓ disclosed herein are suitable for magnetic cooling purposes, for example as a component part of a ferrofluid. It will also be appreciated that the nanoparticles of (Fe₇₀Ni₃₀)₁₀₀₋ₓCrₓ may be suitable for use in the apparatus disclosed hereinbefore.

Although only certain embodiments of the present invention have been described in detail, many variations are possible in accordance with the appended claims. For example, features described in relation to one embodiment may be incorporated into one or more other embodiments and vice versa.

### EXAMPLES

### Methods

The structure and phase of the nanoparticles were determined by X-ray diffraction (XRD) using a Bruker D8 Advance diffractometer (CuKα radiation). The composition was confirmed by energy dispersive X-ray spectroscopy using a JEOL JSM-7600F scanning electron microscope. To determine particle size, transmission electron microscopy (TEM) of nanoparticles was carried out on a JEOL 2010 TEM with an operating voltage of 200 kV. Samples for TEM were prepared by ultrasonically dispersing a small amount of powder in hexane, followed by putting a drop of the suspension on a holey carbon-coated copper grid, the sample is then dried overnight in vacuum. The magnetic properties were measured using a physical property measuring system (PPMS) (EverCool-II, Quantum Design), equipped with a vibrating sample magnetometer probe and an oven (model P527). The M (H) isotherms with field from 0 to 5 T in steps of 5K (near T_{C}) and 10K (elsewhere) were recorded for ΔS_{M} measurements. The isothermal magnetic entropy change due to application of magnetic field was calculated using a numerical approximation to the Maxwell equation

$$Δ {S}_{M} = {\int }_{0}^{M} ( \partial M \text{/} \partial T ) HdH ,$$

where ΔS_{M} is the magnetic entropy change, T is the temperature, M is the magnetization.

### General Procedure 1

High energy ball milling is a suitable technique for producing large-scale, nano- and micro sized materials. This technique is based on mechanical energy transfer created by the collision of hard phase materials with the reactants. Mechanical alloying consists of flattening, welding, fracturing and re-welding of the powder by hard grinding balls. Therefore, alloying of nanostructured powders with defined stoichiometry and crystalline order can be achieved. the high energy ball milling of Fe—Ni—Cr alloy particles was performed.

Nanoparticles of (Fe₇₀Ni₃₀)₁₀₀₋ₓCrₓ alloy were prepared by high energy planetary ball milling (FRITSCH) at 600 rpm under Ar atmosphere from elemental Fe (99.99%, Sigma Aldrich), Ni (99.998%, Fisher ChemAlert Guide) and Cr (>99%, Sigma Aldrich) powders. The ball to powder ratio was 10:1. The vials and balls were made of zirconium oxide, and the volume of the vial was 125 ml, which contains 15 balls (10 mm in diameter).

To prevent oxidation during heat treatment, the magnetic nanoparticles were sealed under high vacuum (10⁻⁵ torr) in a quartz tube. The sealed tube was heated at 700° C. (γ-phase region) for 2 h and quenched in water.⁴ The rate of quenching was ˜125° C./sec.

### Example 1

Six sample materials were prepared according to General Procedure 1. These materials were Fe₇₀Ni₃₀, (Fe₇₀Ni₃₀)₉₉Cr₁, (Fe₇₀Ni₃₀)₉₇Cr₃, (Fe₇₀Ni₃₀)₉₅Cr₅, (Fe₇₀Ni₃₀)₉₄Cr₆, and (Fe₇₀Ni₃₀)₉₃Cr₇, which will be referred to herein as Cr0, Cr1, Cr3, Cr5, Cr6 and Cr7, respectively. 70 wt % of iron and 30 wt % of nickel are used in Cr0. In Cr1, 1 wt % of chromium is added to 99 wt % of the 70:30 iron:nickel mixture and so on.

FIG. 16 shows the XRD patterns of Cr0, Cr1, Cr3, Cr5, Cr6 and Cr7 nanoparticles after heating at 700° C. for 2 h followed by quenching. All the samples exhibit three main diffraction peaks (111, 200 and 220) of the γ-FeNi phase with lattice parameter (a) in the range of 3.5919(4)-3.5983(3) Å and space group Fm-3m. Adding Cr to Fe₇₀Ni₃₀ does not shift in the diffraction peak positions much as the atomic radius of Cr does not differ much from the corresponding value for Fe and Ni. The average crystal sizes, calculated by the Scherrer formula after subtracting the instrumental line broadening, were ˜9 nm, ˜12 nm, ˜10 nm, ˜13 nm, ˜12 nm and ˜11 nm for Cr0, Cr1, Cr3, Cr5, Cr6 and Cr7 nanoparticles, respectively. All the samples exhibit asymmetric broadening in the 111 diffraction peak.

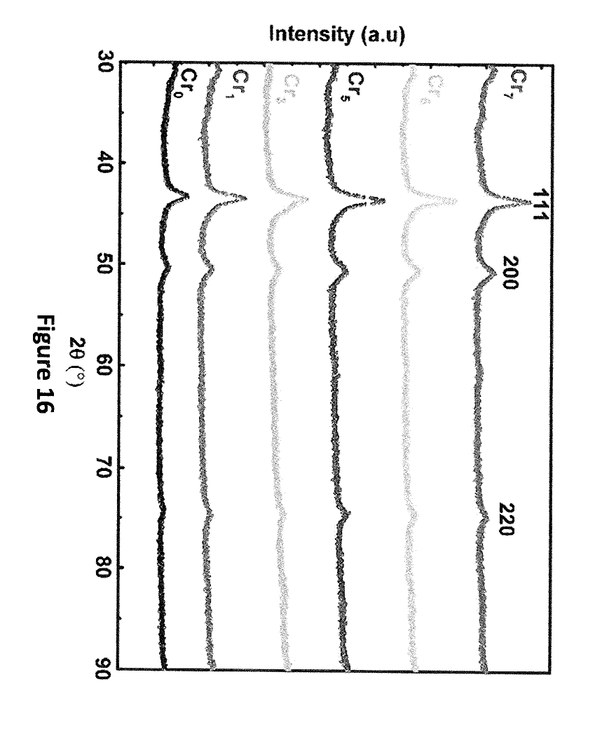

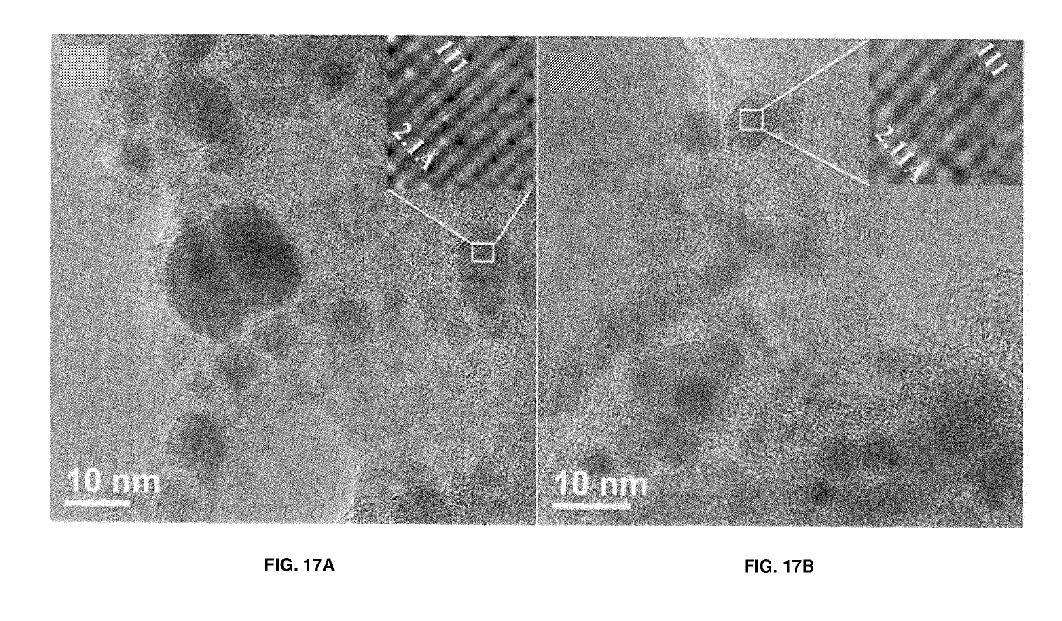

FIGS. 17A and 17B show the bright field transmission electron micrographs of Cr3 and Cr5 nanoparticles. The particle size for Cr3 is in the range of 3 nm to 21 nm, with an average size of 9 nm, while the particle size for Cr5 is in the range of 4 nm to 25 nm range, with an average size of 12 nm. These values are close to the value obtained from XRD data. The lattice fringes of 2.1 Å and 2.11 Å for Cr3 and Cr5, respectively, correspond to the 111 planes of the fcc phase (inset of FIGS. 17A and 17B).

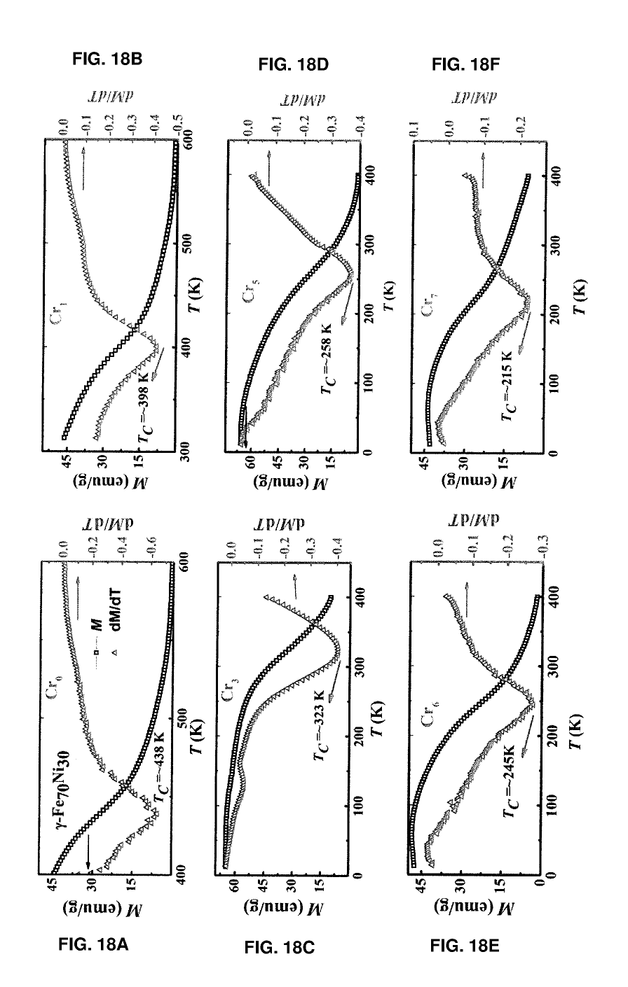

The Curie temperature is the temperature at which the ferromagnetic phase changes to the paramagnetic phase. For MCE applications, we need to determine the T_{C} of that material. It should be noted that the MCE is maximum at its T_{C} and relatively small or almost zero (depending on the T_{C} distribution and the order of the phase transition) at temperatures away from T_{C}. FIGS. 18A, 18B, 18C, 18D, 18E, and 18F show the temperature dependence of magnetization, M(T) (left) and dM/dT (right) for (Fe₇₀Ni₃₀)₁₀₀₋ₓCrₓ (x=0, 1, 3, 5, 6 and 7) nanoparticles, measured upon cooling under a field of 0.1 T. The Curie temperatures (T_{C}) of Cr0, Cr1, Cr3, Cr5, Cr6 and Cr7 were found to be 438 K, 398 K, 323 K, 258 K, 245 K and 215 K, respectively.

T_{C} was determined from the minima of the plot of dM/dT versus T. The reduction of TC can be understand from the mean field model TC=J(r)_{eff} ZT S (S+1)/3k_{B}, where J(r)_{eff} is the effective exchange interaction, ZT is coordination number, S is the atomic spin quantum number and k_{B} is the Boltzmann constant.¹⁶

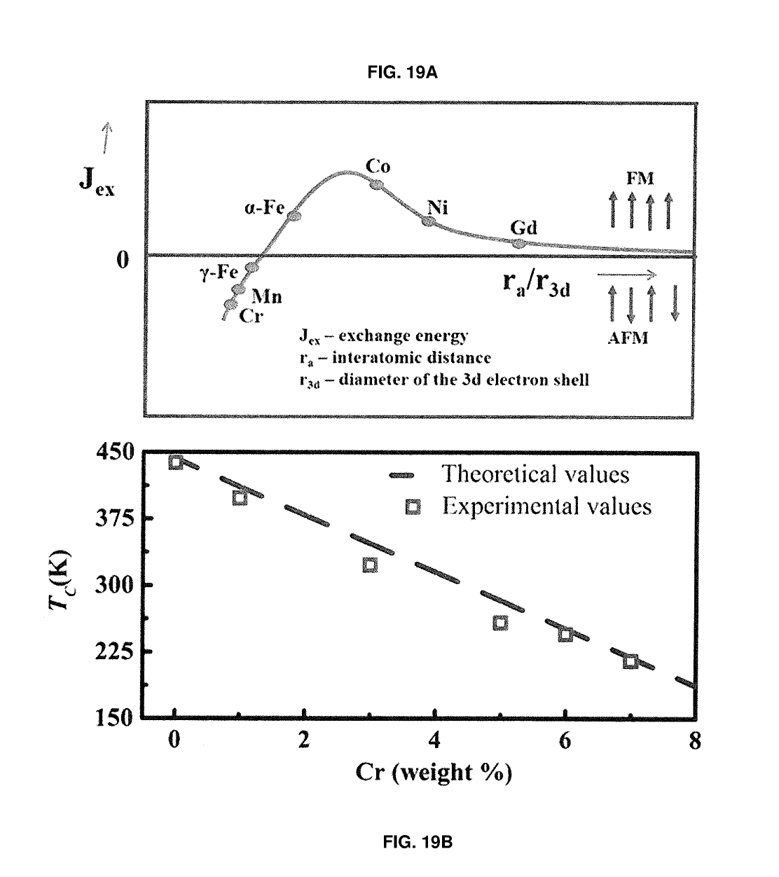

The Bethe-Slater curve qualitatively describes the variation in strength of direct exchange as a function of the ratio of the interatomic distance to diameter of the 3d electrons (rₐ/r_{3d}). A pair interaction of two atoms sharing two electrons can be used to explain the trend of this curve. A value of 1.5 for ferromagnetic spin coupling was assumed empirically in this curve to separate positive from negative exchange interactions (Jex) (FIG. 19(a)). For a ratio rₐ/r_{3d} less than 1.5, when the electrons from two neighbouring atoms are close to each other, the Pauli Exclusion Principle requires the spins of these electrons to be antiparallel, which results in antiferromagnetic interaction between these atoms. If the ratio rₐ/r_{3d} is greater than 1.5, 3d electrons can be further away from each other, filling two different orbital states, resulting in ferromagnetic interactions. After reaching a maximum value, the exchange coupling starts to decrease because of decreasing spatial overlap of the wave functions of the electrons. For the same value of x, T_{C} for (Fe₇₀Ni₃₀)₁₀₀₋ₓCrₓ is lower than that of (Fe₇₀Ni₃₀)₁₀₀₋ₓMnx alloys.^{16,17} This is because the value of J_{CrCr} is more negative than that of J_{MnMn}. Hence, the effective exchange interaction (J_{(r)eff}) is less in the case of (Fe₇₀Ni₃₀)₁₀₀₋ₓCrₓ. The coordination number (ZT) is the same in both cases (due to the same crystal structure), which results in a reduction in T_{C}.

The experimental values of T_{C} were compared with values calculated from the expression T_{C}=T_{C1}+(dT_{C}/dc) c, T_{C1} is the Curie temperature of the parent alloy Fe₇₀Ni₃₀, dT_{C}/dc is the rate of change of Curie temperature with concentration (c). The dT_{C}/dc value for Cr is −3.2×10³ K/at %. A value of T_{C} for Fe₇₀Ni₃₀ was obtained from the binary Fe—Ni phase diagram. This is close to the experimental value of 438 K. FIG. 19(b) shows the change in Curie temperature with Cr % in the ternary system (Fe₇₀Ni₃₀)₁₀₀₋ₓCrₓ.

The dashed blue line and red square represent the expression T_{C}=T_{C1}+(dT_{C}/dc) c and experimental data, respectively. The experimental T_{C} values for Cr0, Cr1, Cr3, Cr6 and Cr7 are reasonably close to those calculated from the expression. This facile tuning of T_{C} makes these alloys useful for near room temperature cooling.

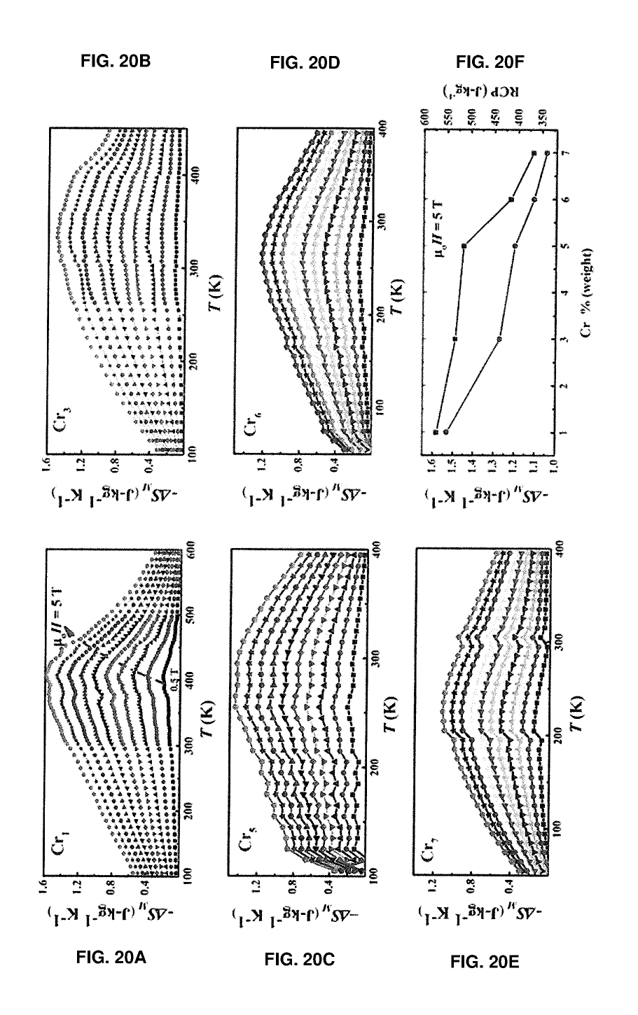

FIGS. 20A, 20B, 20C, 20D, and 20E show the temperature dependences of the magnetic entropy change (−ΔS_{M}) under a range of magnetic fields, ranging from 0.5 T to 5 T for Cr1, Cr3, Cr5, Cr6 and Cr7 alloy, respectively. In all cases, the −ΔS_{M} versus T curves are very broad, exhibiting a table-like shape. There are several reports of the desirability of such table-like shape in magnetocaloric materials for real applications.^{18, 19} Comparing our data to the literature, the −ΔS_{M} and RCP values were calculated at T_{C}. For 1 T applied magnetic field, ΔS_{M} for Cr1, Cr3, Cr5, Cr6 and Cr7 at their T_{C} was found to be 0.38 J-kg⁻¹K⁻¹, 0.27 J-kg⁻¹K⁻¹, 0.37 J-kg⁻¹K⁻¹, 0.29 J-kg⁻¹K⁻¹ and 0.28 J-kg⁻¹K⁻¹, respectively. When the field was increased to 5 T, ΔS_{M} for Cr1, Cr3, Cr5, Cr6 and Cr7 was found to be 1.58 J-kg⁻¹K⁻¹, 1.49 J-kg⁻¹K⁻¹, 1.45 J-kg⁻¹K⁻¹, 1.22 J-kg⁻¹K⁻¹ and 1.11 J-kg⁻¹K⁻¹, respectively.

FIG. 20(f) shows the magnetic entropy change (left axis) and RCP (right axis) vs Cr % (weight) in (Fe₇₀Ni₃₀)₁₀₀₋ₓCrₓ alloy nanoparticles at an applied field of 5 T. Both ΔS_{M} and RCP decrease with increasing Cr % in (Fe₇₀Ni₃₀)₁₀₀₋ₓCrₓ, which can be attributed to antiferromagnetic interactions associated with Cr atoms.

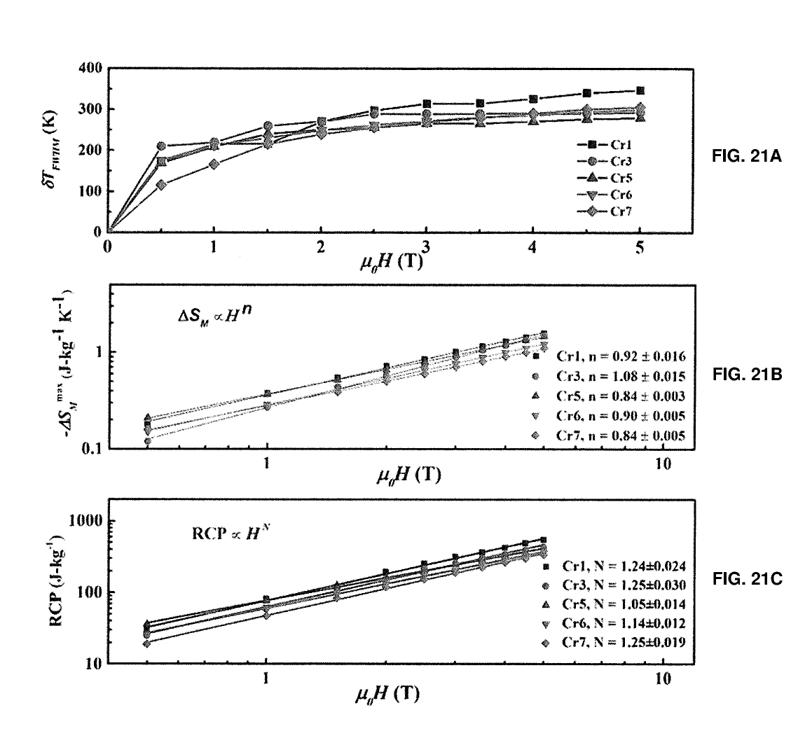

Relative cooling power (RCP) is an important performance metric, it is defined as the product of the maximum change in entropy (ΔS_{M}) and the full width at half maximum (δT_{FWHM}) of the entropy versus temperature curve, i.e., RCP=ΔS_{M}×δT_{FWHM}. FIG. 21(a) shows the variation of (T_{FWHM}, also known as working temperature span, with applied magnetic field.

The δT_{FWHM} for Cr1, Cr3, Cr5, Cr6 and Cr7 was found to be 216K, 220K, 209 K, 213 K and 166 K at magnetic field of 1 T, respectively. Our δT_{FWHM} values are higher than those of Gd (˜35 K), Pr₂Fe₁₇ (˜78 K), Nd₂Fe₁₇ (˜95 K), (Fe₇₀Ni₃₀)₈₉Zr₇B₄ (133 K) at an applied magnetic field of 1 T. Single and multiphase alloys of (Fe₇₀Ni₃₀)₈₉B₁₁ have δT_{FWHM} value of 174 K and 322 K, respectively. Our high working temperature span results in high RCP, which quantifies the magnitude of the heat extracted in a thermodynamic cycle. FIG. 21(c) shows the field dependence of RCP on the log-log scale and the corresponding linear fit. The RCP for Cr1, Cr3, Cr5, Cr6 and Cr7 increased from 82 J-kg⁻¹, 59 J-kg⁻¹, 77 J-kg⁻¹, 62 J-kg⁻¹ and 47 J-kg⁻¹ to 548 J-kg⁻¹, 436 J-kg⁻¹, 406 J-kg⁻¹, 366 J-kg⁻¹ and 306 J-kg⁻¹ as the field increases from ΔH=1 T to ΔH=5 T, respectively.

From the Arrott-Noakes equation of state, the magnetic entropy change at T_{C} can be expressed by the relation ΔS_{M} α Hⁿ, where n=1+[(β−1)/(β+γ)]. The field dependence of RCP can be expressed by the power law RCP α H^{N}, with N=1+1/δ. β, γ and δ are critical exponents. The linear fit of field dependence of ΔS_{M} (FIG. 21(b)) and RCP (FIG. 21(c)) at T_{C} results in values of local exponents “n” and “N”. The values of local exponent “n” at T_{C} for Cr1, Cr3, Cr5, Cr6 and Cr7 were 0.92, 1.08, 0.84, 0.90 and 0.84 respectively, and the values of local exponent “N” at T_{C} for Cr1, Cr3, Cr5, Cr6 and Cr7 were 1.24, 1.25, 1.05, 1.14 and 1.25, respectively. The variation in local exponent can be attributed to different microscopic interactions due to different Cr % in the alloys.

### Example 2

Fe—Ni—Cr nanoparticles were used to prepare the ferrofluid. (Fe₇₀Ni₃₀)₉₅Cr₅ nanoparticles were functionalized with oleic acid and ammonium hydroxide and subjected to high energy ball milling. Subsequently, these coated nanoparticles were dispersed in oleic acid.

Firstly, nanoparticles were synthesized by high energy ball milling in accordance with Example 1 to provide Cr0, Cr1, Cr3, Cr5, Cr6 and Cr7. The resulting nanoparticles were then subjected to further high energy ball milling under the same conditions for 10 hours in the presence of a mixture of oleic acid and ammonium hydroxide in a ratio of 8:2 wt:wt (oleic acid:hydroxide) in the milling vial. The ratio of nanoparticles to coating materials (oleic acid plus ammonium hydroxide) was around 5:1 wt:wt. The resulting coated product was then dispersed in oleic acid at a concentration of 2 vol %.

A ferrofluid of coated Fe—Ni—Cr nanoparticles and oleic acid as made above was then used as the heat transfer medium to perform magnetic cooling.

A 5.2 mm inner diameter, 60 cm circumference polymer tube was used for circular flow. A heat load (electric heater made by Kanthal wires) and a heat sink (cold water) were placed opposite each other. A permanent magnet, which can provide a maximum field of 0.25 T, was placed close to the heat load. A temperature data logger with SD card was used to record temperature v/s time. The initial temperature was tuned by changing current through the Kanthal wire using a Keithley power supply (Model: 2231 A-30-3). For modelling, COMSOL Multiphysics simulation software version 4.4 was used with finite element method and normal mesh.

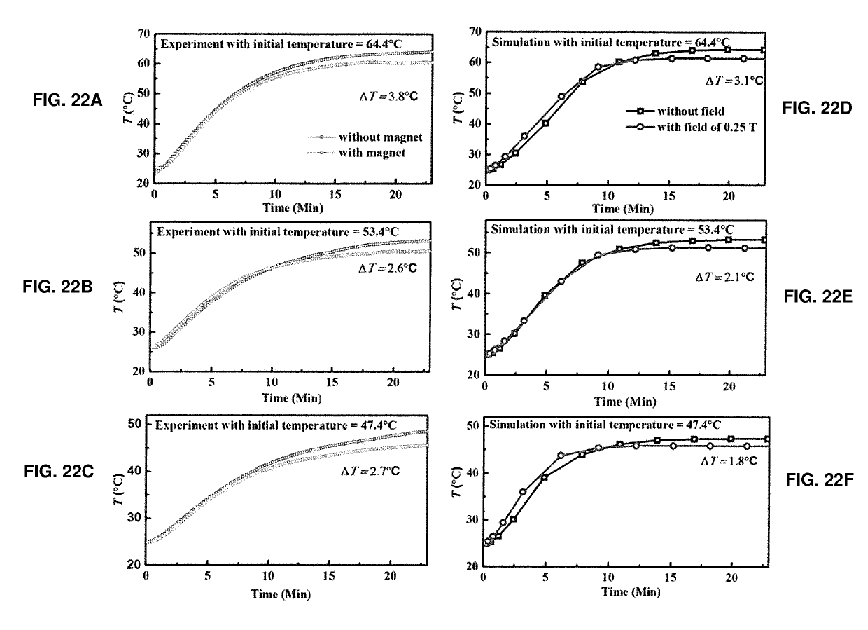

To determine the effect of initial temperature of heat load on cooling, initial heat load temperatures of 64.4° C., 53.4° C. and 47.4° C. were used. A magnetic field of 0.25 T was applied near the heat load. FIGS. 22A, 22B, 22C, 22D, 22E, and 22F show the temperature profiles for heat load for different initial temperature with a magnetic field of 0.25 T and without magnetic field. The results from experiments and simulation show an obvious reduction in temperature (ΔT) in all cases. The value of ΔT increases from 2.7° C. to 3.8° C. when load temperature increases 47.4° C. to 64.4° C., respectively.

These results show that ferrofluid based magnetic cooling is feasible. The experimental results were in good agreement with the simulations for the same magnetic field, other parameters are the same as those used in the experiments.

### REFERENCES

The following references are incorporated herein by reference, with regards to the background of the invention.
1 Rosenweig, R. E. Ferrohydrodynamics (Cambridge University Press, 1985).
2 Love, L. J. Jansen, J. F. McKnight, T. E. Roh, Y. and Phelps, T. J. A magnetocaloric pump for microfluidic applications, NanoBioscience, IEEE Transactions on 3, 101 (2004).
3 Law, J. Y. Franco, V. Keblinski, P. Ramanujan, R. V. Active transient cooling by magnetocaloric materials, 1, 5217-23_(2013).
4 Chaudhary, V. Repaka, D. V. M. Chaturvedi, A. Sridhar I. and Ramanujan, R. V. Magnetocaloric properties and critical behavior of high relative cooling power FeNiB nanoparticles, J. Appl. Phys. 116 (16), 163918-163926 (2014).
5 Fabbri, M., Jiang, S. & Dhir, V. K. A Comparative Study of Cooling of High Power Density Electronics Using Sprays and Microjets. J. Heat Transfer 127, 38-48 (2005).
6 Webb, B. W., and Ma, C. F., Single-Phase Liquid Jet Impingement. Adv. Heat Transfer 26, 105-217 (1995).
7 Lytle, D. & Webb, B. W. Air jet impingement heat transfer at low nozzle-plate spacings. Int. J. Heat Mass Transfer 37, 1687-1697 (1994).
8 Stevens, J. & Webb, B. W. Local Heat Transfer Coefficients Under an Axisymmetric, Single-Phase Liquid Jet. J. Heat Transfer 113, 71-78, doi:10.1115/1.2910554 (1991).
9 Wang, B., Chu, X., Li, E. & Li, L. Simulations and analysis of a piezoelectric micropump. Ultrasonics 44, Supplement, e643-e646 (2006).
10 Stemme, E. & Stemme, G. A valveless diffuser/nozzle-based fluid pump. Sensors and Actuators A: Physical 39, 159-167 (1993).
11 Shinozawa, Y., Abe, T. & Kondo, T. in Micro Electro Mechanical Systems, 1997. MEMS '97, Proceedings, IEEE., Tenth Annual International Workshop on. 233-237.
12 Mattarolo L. Refrigeration and food processing to ensure the nutrition of the growing world population. Progress in the Science and Technology of Refrigeration in Food Engineering, Proceedings of meetings of commissions B2, C2, D1, D2-D3, Sep. 24-28, 1990, Dresden (Germany), Institut International du Froid, Paris (France), 43-54. (1990)
13 Coulomb D. Refrigeration and the cold chain serving the global food industry and creating a better future: two key IIR challenges for improving health and environment. Trends in Food Science & Technology, 19, 413-417 (2008.)
14 https://www.rogerscorp.com/pes/curamik/product/17/curamik-CoolPower-curamik-CoolPower-Plus.aspx
15 http://www.pcworld.com/article/2991413/computers/asus-qx700-deep-dive-heres-whats-inside-the-worlds-first-water-cooled-gaming-laptop.html
16. Chaudhary, V. & Ramanujan, R. V. Magnetic and structural properties of high relative cooling power (Fe₇₀Ni₃₀)₉₂Mn₈ magnetocaloric nanoparticles. J. Phys. D: Appl. Phys. 48, 305003 (2015).
17. Chaudhary, V., Chaturvedi, A., Sridhar, I. & Ramanujan, R. V. Fe—Ni—Mn nanoparticles for near room temperature magnetic cooling. IEEE Magn. Lett. 5, 6800104-6800108 (2014).
18. Fu, H. et al. Table-like magnetocaloric effect in the Gd—Co—Al alloys with multi-phase structure. Appl. Phys. Lett. 104, 072401 (2014).
19. Chaturvedi, A., Stefanoski, S., Phan, M.-H., Nolas, G. S. & Srikanth, H. Table-like magnetocaloric effect and enhanced refrigerant capacity in Eu8Ga16Ge30-EuO composite materials. Appl. Phys. Lett. 99, 162513 (2011).
20. Engelbrecht, et al., Evaluating the effect of magnetocaloric properties on magnetic refrigeration performance. J. Appl. Phys. 108, 123918 (2010).
21. Belyea, D. D., Lucas, M. S., Michel, E., Horwath, J. & Miller, C. W. Tunable magnetocaloric effect in transition metal alloys. Scientific Reports 5, 15755 (2015).
22. Ipus, J. J., Ucar, H. & McHenry, M. E. Near room temperature magnetocaloric response of an (FeNi)ZrB Alloy. IEEE Trans. Magn. 47, 2494-2497 (2011).
23. Ucar, H., Craven, M., Laughlin, D. E. & McHenry, M. E.Effect of Mo addition on structure and magnetocaloric effect in γ-FeNi nanocrystals. J. Electron. Mater. 43, 137-141 (2014).
24. Mathew, S. P. & Kaul, S. N. Tuning magnetocaloric effect with nanocrystallite size. Appl. Phys. Lett. 98, 2505-2508 (2011).
25. Provenzano, V., Shapiro, A. J., Shull & Robert, D. Vol. 429 Nature 5 (Nature Publishing Group, London 2004).

1. An apparatus for transferring heat from a heat source to a heat sink, the apparatus comprising:
a conduit containing a ferrofluid which comprises a plurality of magnetic nanoparticles, a first portion of the conduit being thermally coupleable to the heat source and a second portion of the conduit being thermally coupleable to the heat sink; and
a magnetic element arranged to provide a magnetic field to the ferrofluid;
wherein the magnetic element is located upstream of the first portion to drive a flow of the ferrofluid in the direction of the heat source.

2. The apparatus according to claim 1 wherein the magnetic element is located in a region of the conduit adjacent to the first portion.

3. The apparatus according to claim 1 wherein multiple conduits are employed, each containing a ferrofluid which comprises a plurality of magnetic nanoparticles, and each having a first portion thermally coupleable to the heat source and a second portion thermally coupleable to the heat sink.

4. The apparatus according to claim 3 wherein two or more of the conduits are stacked, nested, aligned, concentric, adjacent or level with each other.

5. The apparatus according to claim 3 wherein an array of conduits is provided.

6. The apparatus according to claim 1 wherein the (or each) conduit is configured as a loop, a helix or a spiral.

7. The apparatus according to claim 6 wherein the (or each) loop, helix or spiral is circular, oval, square, triangular, rectangular or shaped as another polygon or regular or irregular shape.

8. The apparatus according to claim 1 wherein, in use, the (or each) conduit provides a path for the ferrofluid that is substantially horizontal.

9. The apparatus according to claim 1 further comprising a temperature sensor configured to monitor the temperature of the heat source; and a control system configured to adjust the magnetic field provided to the ferrofluid to thereby adjust a cooling rate based on the temperature of the heat source.

10. The apparatus according to claim 9 wherein the magnetic element is constituted by a permanent magnet and the control system is configured to move the permanent magnet towards or away from the ferrofluid to thereby control the magnetic field provided to the ferrofluid.

11. The apparatus according to claim 10 wherein the control system comprises a movable stage configured for moving the permanent magnet.

12. The apparatus according to claim 9 wherein the magnetic element is constituted by an electromagnet and the control system is configured to adjust current flowing through a solenoid wire to thereby control the magnetic field provided to the ferrofluid.

13. The apparatus according to claim 1 further comprising a chamber having an outer portion and an inner portion.

14. The apparatus according to claim 13 wherein the inner portion is configured to accommodate the heat source.

15. The apparatus according to claim 13 wherein the outer portion is configured to accommodate the heat sink.

16. The apparatus according to claim 13 wherein the heat source is arranged centrally within the inner portion of the chamber and one or more heat sinks is arranged in the outer portion of the chamber.

17. The apparatus according to claim 13 wherein both the heat source and the heat sink are provided within the inner portion of the chamber.

18. The apparatus according to claim 1 wherein the first portion of the conduit is arrange to be opposite the second portion of the conduit such that the heat source is arranged to be opposite the heat sink.

19. The apparatus according to claim 1 wherein the magnetic nanoparticles comprise MnZn Ferrite and/or Iron Nickel Chromium alloy.

20. The apparatus according to claim 1 wherein the magnetic nanoparticles comprise Mn_{0.4}Zn_{0.6}Fe₂O₄ and/or (Fe₇₀Ni₃₀)₁₀₀₋ₓCrₓ, where x is from 0 to 7.0, such as (Fe₇₀Ni₃₀)₉₅Cr₅.

21-41. (canceled)
